(19) United States
(12) Patent Application Publication
(10) Pub. No.: US 2024/0306455 A1
(43) Pub. Date: Sep. 12, 2024

(54) DISPLAY APPARATUS

(71) Applicant: Samsung Display Co., Ltd., Yongin-Si (KR)

(72) Inventors: Taehyun Kim, Yongin-si (KR); Kyungmin Kim, Yongin-si (KR); Junhyeong Park, Yongin-si (KR); Gyehwan Lim, Yongin-si (KR)

(21) Appl. No.: 18/599,224

(22) Filed: Mar. 8, 2024

(30) Foreign Application Priority Data
Mar. 10, 2023 (KR) 10-2023-0031879

(51) Int. Cl. H10K 59/131; H10K 59/121

(52) U.S. Cl. CPC H10K 59/131; H10K 59/1213

(57) ABSTRACT

A display apparatus includes a substrate, a main pixel circuit disposed on the substrate and arranged in a front display area, a first lower conductive layer arranged between the substrate and the main pixel circuit, a common power supply wire arranged in the peripheral area, an emission drive circuit arranged in the peripheral area and located at an inner side than the common power supply wire, a gate drive circuit arranged in the second corner display area, and a second lower conductive layer arranged between the substrate and the emission drive circuit, wherein the second lower conductive layer is electrically connected to the common power supply wire, and overlaps the emission drive circuit and the gate drive circuit.

### CROSS-REFERENCE TO RELATED APPLICATION

This application is based on and claims priority under 35 U.S.C. §119 to Korean Patent Application No. 10-2023-0031879, filed on Mar. 10, 2023, in the Korean Intellectual Property Office, the disclosure of which is incorporated by reference herein in its entirety.

### BACKGROUND

### 1. Field

One or more embodiments relate to the structure of a display apparatus, and more particularly, to a display apparatus with an extended display area so that an image may be displayed in a side surface and a corner area.

### 2. Description of the Related Art

Recently, designs of display apparatuses have been diversified. For example, curved surface type display apparatuses, foldable display apparatuses, and rollable display apparatuses have been developed. Furthermore, it is a trend that a display area is expanded and a non-display area is reduced. Accordingly, various methods have been developed to design the shapes of display apparatuses.

### SUMMARY

One or more embodiments include a display apparatus in which a display area is expanded and a peripheral area is reduced, to thus display an image in a corner area. However, such an objective is an example, and the scope of the disclosure is not limited thereby.

Additional aspects will be set forth in part in the description which follows and, in part, will be apparent from the description, or may be learned by practice of the presented embodiments of the disclosure.

According to one or more embodiments, a display apparatus includes a substrate including a front display area, a first corner display area extending from a corner of the front display area, a second corner display area extending from the first corner display area, and a peripheral area surrounding the front display area and the second corner display area, a main pixel circuit disposed on the substrate and arranged in the front display area, a first lower conductive layer arranged between the substrate and the main pixel circuit, a common power supply wire arranged in the peripheral area, an emission drive circuit arranged in the peripheral area and located at an inner side than the common power supply wire, a gate drive circuit arranged in the second corner display area, and a second lower conductive layer arranged between the substrate and the emission drive circuit, wherein the second lower conductive layer may be electrically connected to the common power supply wire, and overlaps the emission drive circuit and the gate drive circuit.

In an embodiment, the second lower conductive layer may include the same material and may be disposed on substantially the same layer as the first lower conductive layer.

In an embodiment, the common power supply wire may include the same material and may be disposed on substantially the same layer as a source electrode or a drain electrode of the main pixel circuit.

In an embodiment, the second lower conductive layer may extend to overlap each of the common power supply wire, the emission drive circuit, and the gate drive circuit, and may be arranged to be separated from the first lower conductive layer.

In an embodiment, the second lower conductive layer may be in direct contact with the common power supply wire through a contact hole.

In an embodiment, the display apparatus may further include an organic insulating layer disposed on the main pixel circuit, the gate drive circuit, and the emission drive circuit, and a power supply electrode layer disposed on the organic insulating layer, wherein the power supply electrode layer may be electrically connected to the second lower conductive layer.

In an embodiment, the main pixel circuit may be connected to a main light-emitting element, and the power supply electrode layer may include the same material as a first electrode of the main light-emitting element, and may be disposed on substantially the same layer as the first electrode.

In an embodiment, the power supply electrode layer may include a plurality of holes in an area overlapping the gate drive circuit.

In an embodiment, the display apparatus may further include a power supply conductive layer arranged between the second lower conductive layer and the power supply electrode layer, wherein the power supply conductive layer may include the same material as the common power supply wire, and may be disposed on substantially the same layer as the common power supply wire.

In an embodiment, the peripheral area may further include a valley area arranged between the emission drive circuit and the gate drive circuit, and the second lower conductive layer, the power supply conductive layer, and the power supply electrode layer are electrically connected to one another in the valley area.

In an embodiment, each of the emission drive circuit and the gate drive circuit may include a buffer transistor, the buffer transistor may include an input electrode, an output electrode, and a control electrode, and the control electrode may have a structure in which a first metal layer and a second metal layer overlap each other.

In an embodiment, the first metal layer and the second metal layer may be disposed on different layers with an insulating layer interposed therebetween, and may be electrically connected to each other through a contact hole.

In an embodiment, the display apparatus may further include a buffer layer disposed on the first lower conductive layer and the second lower conductive layer, a semiconductor layer disposed on the buffer layer, a first gate insulating layer disposed on the semiconductor layer, a first gate layer disposed on the first gate insulating layer, a second gate insulating layer disposed on the first gate layer, a second gate layer disposed on the second gate insulating layer, a first interlayer insulating layer disposed on the second gate layer, and a third gate layer disposed on the first interlayer insulating layer.

In an embodiment, the first metal layer may include the same material and may be disposed on substantially the same layer as the second lower conductive layer, and the second metal layer may include the same material and may be disposed on substantially the same layer as the first gate layer.

In an embodiment, the first metal layer may include the same material and may be disposed on substantially the same layer as the second gate layer, and the second metal layer may include the same material and may be disposed on substantially the same layer as the third gate layer.

In an embodiment, the buffer transistor may include a first buffer transistor and a second buffer transistor, a first metal layer of the first buffer transistor and a first metal layer of the second buffer transistor are disposed on different layers, and the second metal layer of the first buffer transistor and the second metal layer of the second buffer transistor are disposed on different layers.

In an embodiment, the first metal layer of the first buffer transistor may be disposed on substantially the same layer as the second lower conductive layer, the second metal layer of the first buffer transistor may be disposed on substantially the same layer as the first gate layer, the first metal layer of the second buffer transistor may be disposed on substantially the same layer as the second gate layer, and the second metal layer of the second buffer transistor may be disposed on substantially the same layer as the third gate layer.

In an embodiment, the display apparatus may further include first signal input lines through which signals are input to the emission drive circuit, and second signal input lines through which signals are input to the gate drive circuit, wherein some lines of the first signal input lines and some lines of the second signal input lines are disposed on different layers.

In an embodiment, the display apparatus may further include a first organic insulating layer covering the main pixel circuit, and a first connection electrode disposed on the first organic insulating layer and connecting the main pixel circuit with a main light-emitting element, wherein the first signal input lines may be disposed on substantially the same layer as a source electrode or a drain electrode of the main pixel circuit, and the second signal input lines may be disposed on substantially the same layer as the first connection electrode.

According to one or more embodiments, a display apparatus includes a substrate including a display area and a peripheral area surrounding the display area, an emission drive circuit disposed on the substrate, and a gate drive circuit disposed on the substrate and arranged closer to the display area than the emission drive circuit, wherein each of the emission drive circuit and the gate drive circuit may include a buffer transistor, the buffer transistor may include an input electrode, an output electrode, and a control electrode, and the control electrode has a structure in which a first metal layer and a second metal layer overlap each other.

In an embodiment, the first metal layer and the second metal layer may be disposed on different layers with an insulating layer therebetween, and are electrically connected to each other through a contact hole.

In an embodiment, the display apparatus may further include first signal input lines through which signals are input to the emission drive circuit, and second signal input lines through which signals are input to the gate drive circuit, wherein some lines of the first signal input lines and some lines of the second signal input lines are disposed on different layers.

In an embodiment, the display apparatus may further include a pixel circuit disposed on the substrate and arranged in the display area, a first lower conductive layer arranged between the substrate and the pixel circuit, a common power supply wire arranged in the peripheral area, and a second lower conductive layer electrically connected to the common power supply wire, wherein the first lower conductive layer and the second lower conductive layer are disposed on substantially the same layer, and the second lower conductive layer overlaps the emission drive circuit and the gate drive circuit.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to an embodiment;

FIG. 2 is a schematic exploded perspective view of a display panel and a cover window of a display apparatus according to an embodiment;

FIG. 3 is a schematic perspective view of a display panel of a display apparatus according to an embodiment;

FIG. 4 is a cross-sectional view of the display apparatus of FIG. 1 taken along a line I-I′ of FIG. 1;

FIG. 5 is a schematic plan view of a display panel in an unfolded state, which may be included in the display apparatus of FIG. 1, according to an embodiment;

FIG. 6 is an enlarged view of a region II of FIG. 5;

FIG. 7 is a schematic cross-sectional view of a portion of a display apparatus according to an embodiment, which corresponds to a cross-section taken along a line III-III′ of FIG. 6;

FIGS. 8A and 9A each are equivalent circuit diagrams of a pixel circuit that is applicable to a display apparatus according to an embodiment;

FIGS. 8B and 9B each are schematic diagrams of the configuration of a display apparatus according to an embodiment;

FIGS. 10A and 10B are schematic diagrams of a drive circuit according to an embodiment;

FIG. 11 is a schematic plan view of a portion of a display apparatus according to an embodiment, which corresponds to an enlarged view of a region A of FIG. 6;

FIG. 12 is a schematic cross-sectional view of a portion of a display apparatus according to an embodiment, which corresponds to a cross-section taken along a line IV-IV′ of FIG. 11;

FIG. 13 is a schematic plan view of a buffer transistor of a display apparatus according to an embodiment;

FIG. 14A is a schematic cross-sectional view of a portion of a display apparatus according to an embodiment, which corresponds to a cross-section taken along a line V-V′ of FIG. 13; and

FIG. 14B is a schematic cross-sectional view of a portion of a display apparatus according to another embodiment, which corresponds to a cross-section taken along a line V-V′ of FIG. 13.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to the present embodiments, and particular embodiments will be illustrated in the drawings and described in the detailed description section. The effect and features of the present embodiments, and a method to achieve the same, will be clearer referring to the detailed descriptions below with the drawings. However, the present embodiments may be implemented in various forms, not by being limited to the embodiments presented below.

Hereinafter, exemplary embodiments will be described in detail with reference to the accompanying drawings, and in the description with reference to the drawings, the same or corresponding constituents are indicated by the same reference numerals and redundant descriptions thereof are omitted.

In the following embodiment, it will be understood that although the terms first, second, etc. may be used herein to describe various elements, these elements should not be limited by these terms. These elements are only used to distinguish one element from another.

In the following embodiment, as used herein, the singular forms “a,” “an,” and “the” are intended to include the plural forms as well, unless the context clearly indicates otherwise.

In the following embodiment, it will be further understood that the terms “comprises” and/or “comprising” used herein specify the presence of stated features or elements, but do not preclude the presence or addition of one or more other features or components.

In the following embodiment, it will be understood that when an element, such as a layer, a film, a region, or a plate, is referred to as being ‘on’ another element, the element can be directly on the other element or intervening elements may be present thereon.

Sizes of elements in the drawings may be exaggerated for convenience of explanation. For example, since sizes and thicknesses of elements in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

In the following embodiment, it will be understood that when a layer, region, or component is referred to as being ‘connected to’ another layer, region, or component, it can be directly connected to the other layer, region, or component or indirectly connected to the other layer, region, or component via intervening layers, regions, or components. For example, in the specification, when a layer, region, or component is referred to as being electrically connected to another layer, region, or component, it can be directly electrically connected to the other layer, region, or component or indirectly electrically connected to the other layer, region, or component via intervening layers, regions, or components.

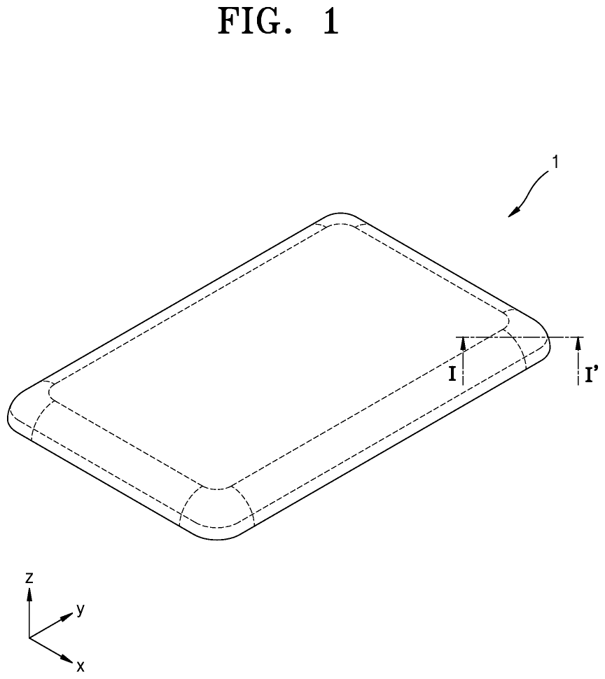

FIG. 1 is a schematic perspective view of a display apparatus 1 according to an embodiment.

Referring to FIG. 1, the display apparatus 1 according to an embodiment, as an apparatus for displaying a video or a still image, may include portable electronic apparatuses, such as mobile phones, smart phones, tablet personal computers (PCs), mobile communication terminals, electronic organizers, electronic books, portable multimedia players (PMPs), navigation devices, ultra-mobile PCs (UMPCs), and the like. Furthermore, the display apparatus 1 may include electronic apparatuses that provide display screens of televisions, notebook computers, monitors, billboard, internet of things (IOT), and the like. Alternatively, the display apparatus 1 may include wearable devices, such as smart watches, watch phones, glasses-type displays, or head mounted displays (HMD).

In an embodiment, the display apparatus 1 may have a rectangular shape in a plan view. In an optional embodiment, the display apparatus 1 may have various shapes, such as a polygonal shape such as a triangle, a rectangle, and the like, a circular shape, an oval shape, and the like. In an embodiment, when the display apparatus 1 has a polygonal shape in a plan view, a polygonal corner may be rounded. Hereinbelow, for convenience of explanation, a case in which the display apparatus 1 has a rectangular shape with a rounded corner in a plan view is mainly described.

The display apparatus 1 may have a short side in a first direction (for example, an x direction or a-x direction) and a long side in a second direction (for example, a y direction or a-y direction). In another embodiment, in the display apparatus 1, the length of a side in the first direction (for example, the x direction or the −x direction) may be the same as the length of a side in the second direction (for example, the y direction or the −y direction). In another embodiment, the display apparatus 1 may have a long side in the first direction (for example, the x direction or the −x direction) and a short side in the second direction (for example, the y direction or the −y direction). Each corner where the short side in the first direction (for example, the x direction or the −x direction) meets the long side in the second direction (for example, the y direction or the −y direction) may be rounded to have a certain curvature.

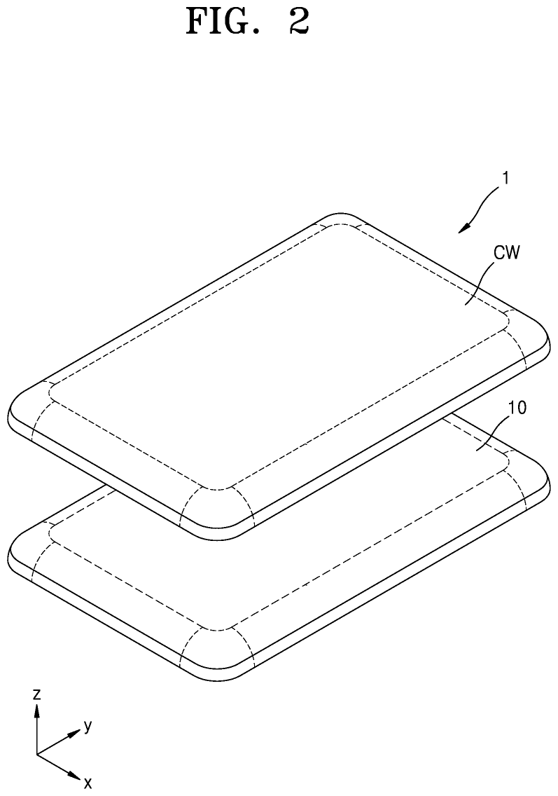

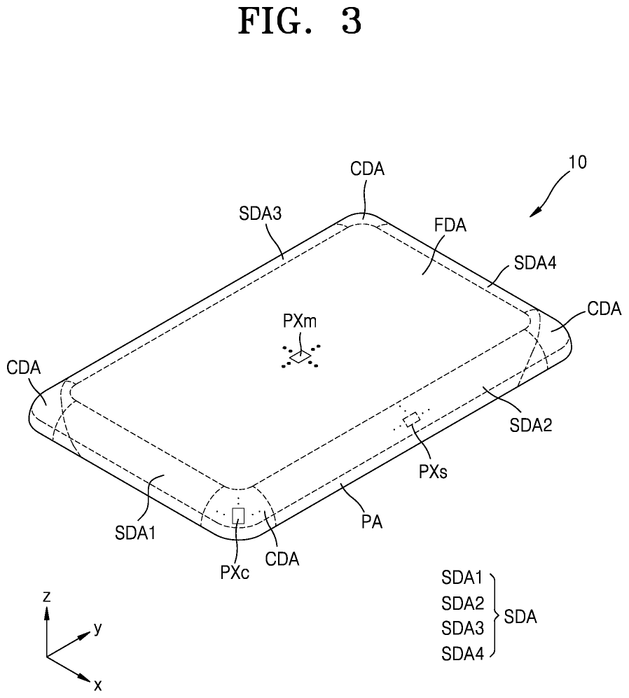

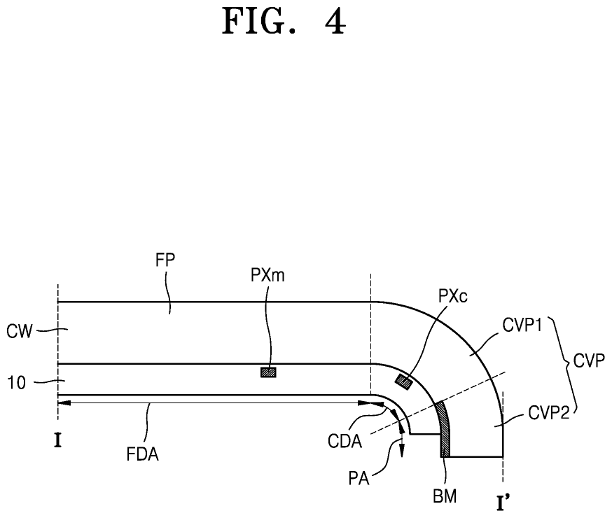

FIG. 2 is a schematic exploded perspective view of a display panel 10 and a cover window CW of the display apparatus 1, according to an embodiment. FIG. 3 is a schematic perspective view of the display panel 10 of a display apparatus according to an embodiment. FIG. 4 is a cross-sectional view of the display apparatus of FIG. 1 taken along a line I-I′ of FIG. 1.

Referring to FIGS. 2 to 4, the display apparatus 1 may include the display panel 10 and a cover window CW disposed on the display panel 10.

The display panel 10 may include, as a display area, a front display area FDA, a side display area SDA, and a corner display area CDA. The display apparatus 1 may include a peripheral area PA surrounding the display area.

The front display area FDA is an area arranged in the front surface portion of the display panel 10 and formed to be flat without bending. The front display area FDA may have the largest percentage of the display area of the display panel 10, and thus, may provide most of an image. In other words, the front display area FDA may be a main display area. The front display area FDA includes a short side in the x direction and a long side in the y direction, and each corner where the short side meets the long side may be rounded.

The side display area SDA may extend outward from each side of the front display area FDA, and include a curved surface formed as at least a portion thereof is bent. The side display area SDA may include a first side display area SDA1, a second side display area SDA2, a third side display area SDA3, and a fourth side display area SDA4. In some embodiments, at least one of the first side display area SDA1, the second side display area SDA2, the third side display area SDA3, or the fourth side display area SDA4 may be omitted.

The first side display area SDA1 may be an area extending from a first side of the front display area FDA and bent at a certain curvature. The first side display area SDA1 may extend from a lower side of the front display area FDA. The first side display area SDA1 may be an area arranged on a lower side surface of the display panel 10.

The second side display area SDA2 may be an area extending from a second side of the front display area FDA and bent at a certain curvature. The second side display area SDA2 may extend from the right side of the front display area FDA. The second side display area SDA2 may be an area arranged on the right side surface of the display panel 10.

The third side display area SDA3 may be an area extending from a third side of the front display area FDA and bent at a certain curvature. The third side display area SDA3 may extend from the left side of the front display area FDA. The third side display area SDA3 may be an area arranged on a left side surface of the display panel 10.

The fourth side display area SDA4 may be an area extending from a fourth side of the front display area FDA and bent at a certain curvature area. The fourth side display area SDA4 may extend from an upper side of the front display area FDA. The fourth side display area SDA4 may be an area arranged on an upper side surface of the display panel 10.

The first to fourth side display areas SDA1, SDA2, SDA3, and SDA4 may each include a curved surface bent at a certain curvature. For example, the first side display area SDA1 and the fourth side display area SDA4 may each have a curved surface bent around a bending axis extending in the x direction, whereas the second side display area SDA2 and the third side display area SDA3 may each have a curved surface bent around a bending axis extending in the y direction. The curvatures of the first to fourth side display areas SDA1, SDA2, SDA3, and SDA4 may be the same or different from each other.

The corner display area CDA may be an area extending from each corner of the front display area FDA and bent at a certain curvature. The corner display area CDA may be arranged between adjacent side display areas SDA. For example, the corner display area CDA may be arranged between the first side display area SDA1 and the second side display area SDA2, between the first side display area SDA1 and the third side display area SDA3, between the second side display area SDA2 and the fourth side display area SDA4, and between the third side display area SDA3 and the fourth side display area SDA4.

As the corner display area CDA is located between the adjacent side display areas SDA neighboring each other and having curved surfaces bent in different directions, the corner display area CDA may include a curved surface that continuously adjoins curved surfaces bent in various directions. Furthermore, when the curvatures of the side display areas SDA neighboring each other are different from each other, the curvature of the corner display area CDA may be gradually changed along the edge of the display apparatus 1. For example, when the curvature of the first side display area SDA1 is different from the curvature of the second side display area SDA2, the corner display area CDA between the first side display area SDA1 and the second side display area SDA2 may have a curvature that gradually changes according to a position.

The display panel 10 may provide an image by using a plurality of main pixels PXm arranged in the front display area FDA, a plurality of side pixels PXs arranged in the side display area SDA, and corner pixels PXc arranged in the corner display area CDA. The display panel 10 provides an image through the side display area SDA and the corner display area CDA in addition to the front display area FDA, so that a proportion of the display area of the display apparatus 1 may increase. In other words, in the display apparatus 1 having the same size, the size of the peripheral area PA may decrease and the size of the display area may increase.

The peripheral area PA may be arranged to entirely or partially surround the outer edges of the side display area SDA and the corner display area CDA. The peripheral area PA is where an image is not displayed and various wires, drive circuits, and the like may be arranged. A screen such as a light blocking member may be provided in the peripheral area PA so that components arranged in the peripheral area PA may not be seen.

Referring to FIG. 4, the cover window CW may be disposed on the front surface of the display panel 10. The front surface of the display panel 10 may be defined as a surface of the display panel 10 in a direction in which an image is provided.

The cover window CW may cover and protect the display panel 10. The cover window CW may have a high transmittance to transmit light emitted from the display panel 10, and a thin thickness to reduce the weight of the display apparatus 1. Furthermore, the cover window CW may have high strength and hardness to protect the display panel 10 from external impacts.

The cover window CW may include a transparent material. The cover window CW may include, for example, glass or plastic. When the cover window CW includes plastic, the cover window CW may be flexible. For example, the cover window CW may include ultra-thin tempered glass (Ultra-Thin Glass or UTG®) of which strength is reinforced by a chemical reinforcement method, a thermal reinforcement method, or the like. In another embodiment, the cover window CW may include tempered glass (Ultra-Thin Glass, UTG®) and transparent polyimide (Colorless Polyimide or CPI). In an embodiment, the cover window CW may have a structure in which a flexible polymer layer is arranged on one surface of a glass substrate, or may be formed of only a polymer layer.

The cover window CW may include a flat portion FP disposed in an area corresponding to the front display area FDA of the display panel 10 and a curved portion CVP disposed in an area corresponding to the side display area SDA and the corner display area CDA.

The flat portion FP of the cover window CW is flat and may overlap the front display area FDA of the display panel 10. The curved portion CVP of the cover window CW may be a curved surface, and in this case, the curved portion CVP may have a certain curvature or a varying curvature. The curved portion CVP may include a first curved portion CVP1 and a second curved portion CVP2. The first curved portion CVP1 may be arranged to overlap the side display area SDA and the corner display area CDA of the display panel 10. The second curved portion CVP2 may be arranged to overlap the peripheral area PA of the display panel 10. The first curved portion CVP1 may be arranged between the flat portion FP and the second curved portion CVP2.

A light blocking member BM may be arranged in a portion of the second curved portion CVP2 of the cover window CW. The light blocking member BM for covering a lower structure thereunder may be arranged to overlap the peripheral area PA of the display panel 10. The light blocking member BM may include a light blocking material. The light blocking member BM may include resin including carbon black, carbon nanotube, or black dye. Alternatively, the light blocking member BM may include nickel, aluminum, molybdenum, or an alloy thereof, and the like. The light blocking member BM may be coated by an inkjet method or attached as a film type.

The display panel 10 may be arranged below the cover window CW. The cover window CW and the display panel 10 may be bonded to each other through an adhesive member (not shown). The adhesive member may include a transparent adhesive film (an optically cleared adhesive film or OCA) or transparent adhesive resin (optically cleared resin or OCR).

The display panel 10 may provide an image by using the main pixels PXm arranged in the front display area FDA, and the corner pixels PXc arranged in the corner display area CDA. A lower protection film (not shown) for protecting the display panel 10 may be arranged below the display panel 10.

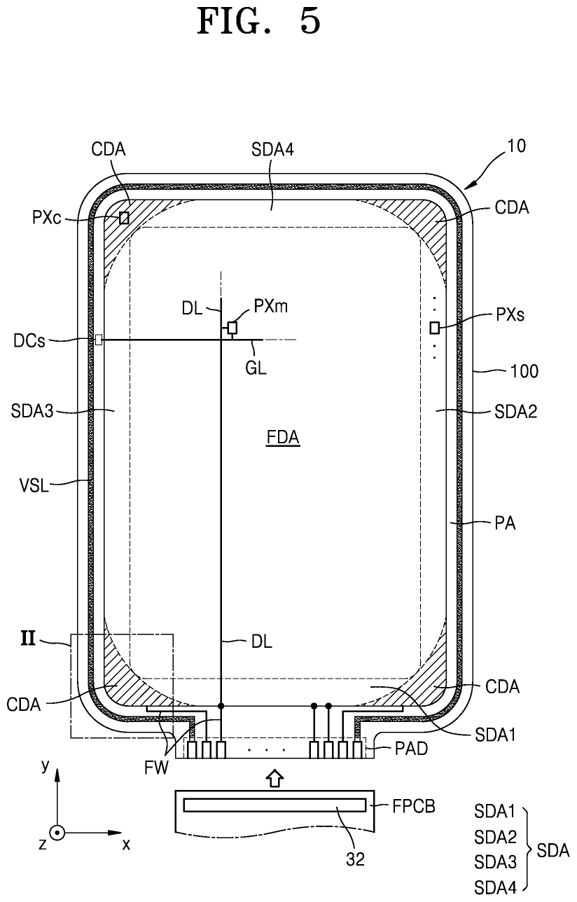

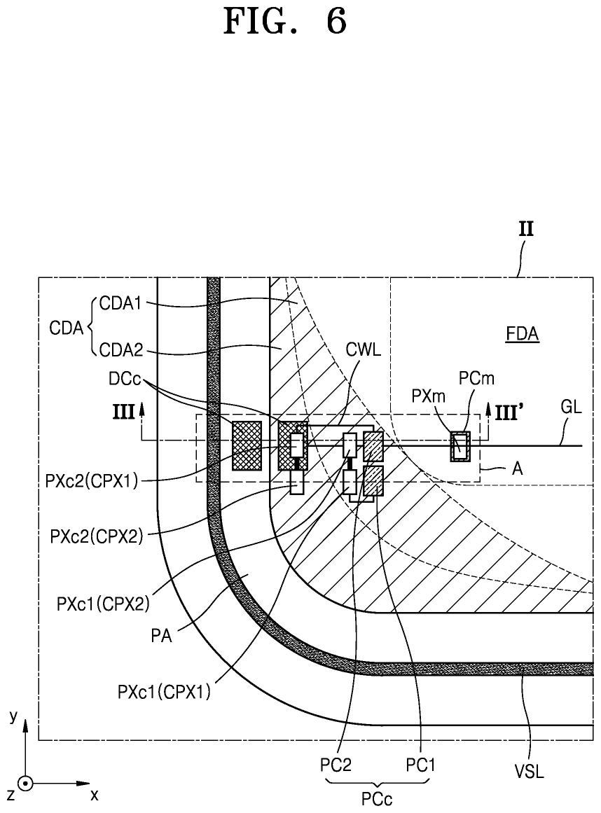

FIG. 5 is a schematic plan view of a display panel in an unfolded state, which may be included in the display apparatus of FIG. 1, according to an embodiment. FIG. 6 is an enlarged view of a region II of FIG. 5.

Referring to FIGS. 5 and 6, various constituent elements forming the display panel 10 are arranged on a substrate 100. The substrate 100 may include the front display area FDA, the side display area SDA, the corner display area CDA, and the peripheral area PA.

The main pixels PXm may be arranged in the front display area FDA, and by which a main image may be displayed. Each of the main pixels PXm may be provided as a set of a plurality of sub-pixels. Each sub-pixel may emit red, green, blue, or white light.

The side display area SDA may be arranged in the top, bottom, left, and right sides of the front display area FDA. The side pixels PXs may be arranged in the side display area SDA, by which a side image may be displayed. The side image may form one whole image with the main image or may be an image independent of the main image.

The corner display area CDA may be arranged in an area extending from the corner of the front display area FDA. The corner display area CDA may be arranged between the adjacent side display areas SDA. A plurality of first corner pixels PXc1 and a plurality of second corner pixels PXc2 may be arranged in the corner display area CDA, by which a corner image may be displayed. The corner image may form one whole image with the main image and the side image, or may be an image independent of the main image.

Each of the corner display area CDA may include a first corner display area CDA1 and a second corner display area CDA2. The second corner display area CDA2, which is an area extending from the first corner display area CDA1, may be arranged closer to an edge of the substrate 100 than the first corner display area CDA1. The first corner display area CDA1 may be arranged between the second corner display area CDA2 and the front display area FDA. The first corner pixels PXc1 may be arranged in the first corner display area CDA1, and the second corner pixels PXc2 may be arranged in the second corner display area CDA2.

In addition to the second corner pixels PXc2, a corner drive circuit DCc may be arranged in the second corner display area CDA2. The corner drive circuit DCc arranged in the second corner display area CDA2 may be a gate drive circuit. In other words, the corner drive circuit DCc may provide a scan signal to drive the main pixels PXm and the first and second corner pixels PXc1 and PXc2 respectively arranged in the front display area FDA and the corner display area CDA. In some embodiments, the corner drive circuit DCc may be simultaneously connected to a pixel circuit for driving the first and second corner pixels PXc1 and PXc2 and a pixel circuit for driving the main pixels PXm and may provide the same scan signals thereto. In this case, a gate line GL connected to the corner drive circuit DCc may extend from the second corner display area CDA2 toward the front display area FDA. The gate line GL may extend in the x direction.

In the second corner display area CDA2, the second corner pixels PXc2 may be arranged to overlap the corner drive circuit DCc. A pixel circuit PC for driving the second corner pixels PXc2 arranged in the second corner display area CDA2 may be arranged in the first corner display area CDA1. Accordingly, first and second corner pixel circuits PC1 and PC2 for driving the first corner pixel PXc1 arranged in the first corner display area CDA1 and the second corner pixels PXc2 arranged in the second corner display area CDA2, respectively, may be arranged in the first corner display area CDA1. The second corner pixels PXc2 arranged in the second corner display area CDA2 may be connected to the second corner pixel circuit PC2 arranged in the first corner display area CDA1 through a connection wire CWL, and driven by the second corner pixel circuit PC2. The connection wire CWL may extend in the x direction in which the gate line GL extends.

The first and second corner pixels PXc1 and PXc2 arranged in the corner display area CDA may include a first copy pixel CPX1 and a second copy pixel CPX2, respectively. The first copy pixel CPX1 and the second copy pixel CPX2 may be driven by one pixel circuit, and may emit light of the same color. The sizes of the first copy pixel CPX1 and the second copy pixel CPX2 may be substantially the same. As the first and second corner pixels PXc1 and PXc2 are provided as copy pixels, the number of circuits for driving the first and second corner pixels PXc1 and PXc2 may be reduced, and as the second corner pixels PXc2 are arranged to overlap the corner drive circuit DCc, the corner display area CDA may be expanded.

The peripheral area PA may be arranged outside the side display area SDA and the corner display area CDA. Various wires including a common power supply wire VSL, a side drive circuit DCs, the corner drive circuit DCc, and a terminal portion PAD may be provided in the peripheral area PA.

The side drive circuit DCs may include an emission drive circuit and a gate drive circuit. In other words, the side drive circuit DCs may provide a scan signal to drive the main pixels PXm and the side pixels PXs, and may output an emission control signal. The side drive circuit DCs may be arranged at the right side of the second side display area SDA2 and/or at the left side of the third side display area SDA3, and may be connected to the gate line GL extending in the x direction.

The corner drive circuit DCc arranged in the peripheral area PA may be an emission drive circuit. In other words, the corner drive circuit DCc arranged in the peripheral area PA may output emission control signals to drive main pixels PXm and the corner pixels PXc.

The terminal portion PAD may be arranged at the bottom side of the first side display area SDA1. The terminal portion PAD is not covered by an insulating layer but is exposed through a contact hole formed in the insulating layer and connected to a display circuit board FPCB. A display driver 32 may be arranged on the display circuit board FPCB.

The display driver 32 may generate control signals that are transmitted to the side and corner drive circuits DCs and DCc. Furthermore, the display driver 32 may generate data signals. The generated data signals may be transmitted to the main, side, and corner pixels PXm, PXs, and PXc through a fan-out wire FW and a data line DL connected to the fan-out wire FW.

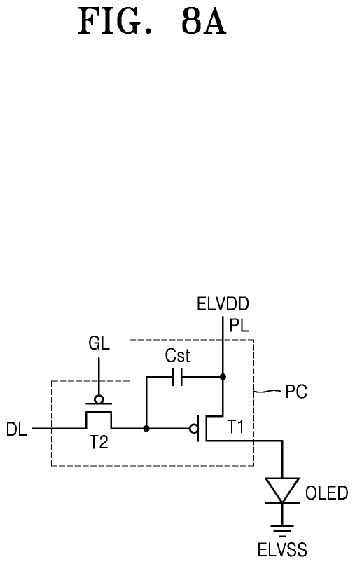

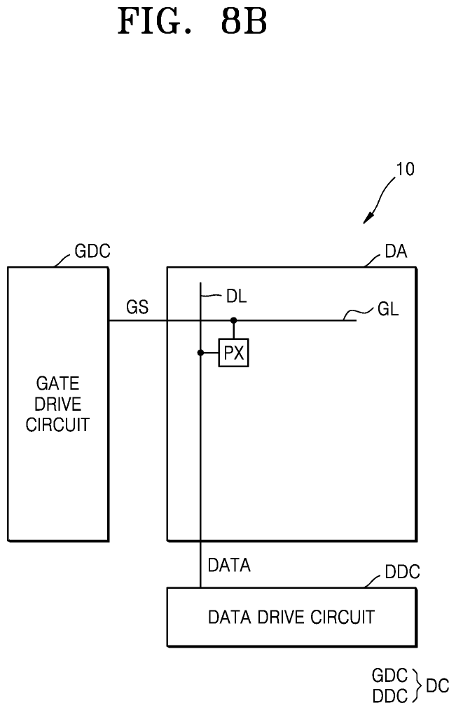

The common power supply wire VSL may be a power wire through which a common voltage ELVSS of FIG. 8A is received and transmitted to the main and side pixels PXm and PXs. The common power supply wire VSL may be arranged in the peripheral area PA to at least partially surround the front display area FDA, the side display area SDA, and the corner display area CDA. The common power supply wire VSL may have a loop shape with one open side. The common power supply wire VSL may be arranged outside of the side drive circuit DCs to surround the side drive circuit DCs.

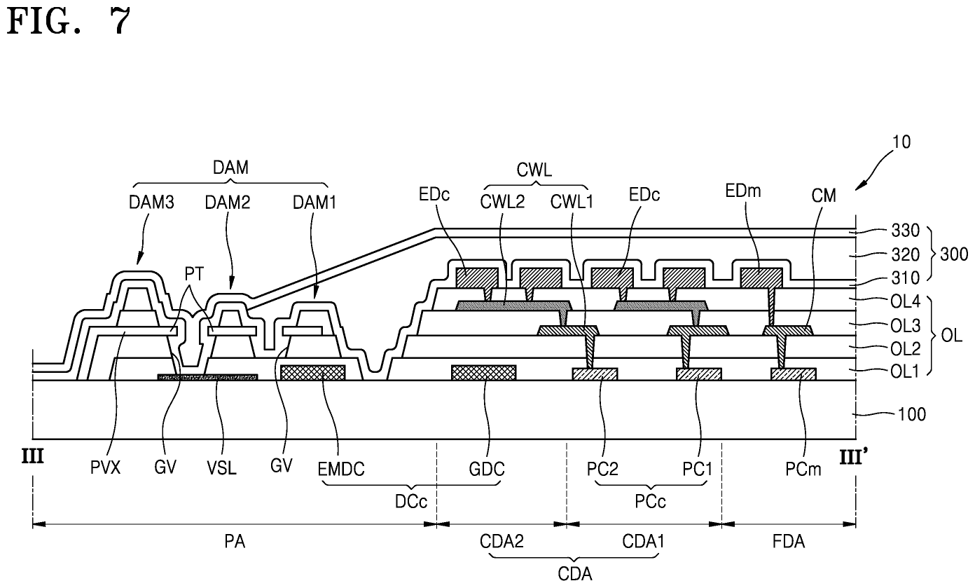

FIG. 7 is a schematic cross-sectional view of a portion of a display apparatus according to an embodiment, which corresponds to a cross-section taken along a line III-III′ of FIG. 6.

Referring to FIG. 7, the display panel 10 may include the front display area FDA, the corner display area CDA, and the peripheral area PA. The corner display area CDA may include the first corner display area CDA1 and the second corner display area CDA2.

The substrate 100 may include an insulating material, such as glass, quartz, polymer resin, and the like. The substrate 100 may include a rigid substrate or a flexible substrate capable of bending, folding, rolling, and the like.

Main and corner pixel circuits PCm and PCc including thin film transistors, the corner drive circuit DCc providing signals to the pixel circuits, main and corner light-emitting elements EDm and EDc connected to the pixel circuits and constituting pixels, a thin film encapsulation layer 300 covering and protecting the main and corner light-emitting elements EDm and EDc, and a dam DAM may be arranged on the substrate 100. The pixel circuits may include the main pixel circuit PCm and the corner pixel circuit PCc, and the corner pixel circuit PCc may include the first corner pixel circuit PC1 and the second corner pixel circuit PC2. In some embodiments, the main pixel circuit PCm, the first corner pixel circuit PC1 and the second corner pixel circuit PC2 may all be provided as the same pixel circuit. In another embodiment, the main pixel circuit PCm, the first corner pixel circuit PC1, and the second corner pixel circuit PC2 may be provided as at least partially modified pixel circuits or as different pixel circuits.

An organic insulating layer OL may be arranged between the main and corner pixel circuits PCm and PCc and the main and corner light-emitting elements EDm and EDc. The organic insulating layer OL may include a plurality of organic insulating layers which are stacked. In some embodiments, the organic insulating layer OL may include a first organic insulating layer OL1, a second organic insulating layer OL2, a third organic insulating layer OL3, and a fourth organic insulating layer OL4.

The main pixel circuit PCm and the main light-emitting element EDm connected to the main pixel circuit PCm may be arranged in the front display area FDA of the display panel 10. The emission area of the main light-emitting element EDm may be disposed in an area corresponding to the main pixel PXm of FIG. 6. The main pixel circuit PCm may include at least one thin film transistor, and the light-emission of the main light-emitting element EDm may be controlled by the at least one thin film transistor. The main light-emitting element EDm may be connected to the main pixel circuit PCm through a connection electrode CM. The main light-emitting element EDm may overlap at least a part of the main pixel circuit PCm.

The first corner pixel circuit PC1 and the corner light-emitting element EDc connected to the first corner pixel circuit PC1 may be arranged in the first corner display area CDA1 of the display panel 10. The emission area of the corner light-emitting element EDc may be disposed in an area corresponding to the corner pixel PXc of FIG. 6. The first corner pixel circuit PC1 may include at least one thin film transistor which controls the light-emission of at least two corner light-emitting elements EDc. In an embodiment, two corner light-emitting elements EDc may be connected to one first corner pixel circuit PC1 to simultaneously emit light. In this case, the two corner light-emitting elements EDc may constituting copy pixels.

The second corner pixel circuit PC2 connected to the corner light-emitting element EDc arranged in the second corner display area CDA2 may be arranged in the first corner display area CDA1. The second corner pixel circuit PC2 may include at least one thin film transistor, and the at least one thin film transistor controls the light-emission of at least two corner light-emitting elements EDc. In an embodiment, the two corner light-emitting elements EDc may be connected to one second corner pixel circuit PC2 to simultaneously emit light. In this case, two corner light-emitting elements EDc may constituting copy pixels.

The second corner pixel circuit PC2 may be connected to the corner light-emitting element EDc arranged in the second corner display area CDA2 through the connection wire CWL. The connection wire CWL may include a first connection wire CWL1 and a second connection wire CWL2 arranged on different layers. The second corner pixel circuit PC2 may be connected to the corner light-emitting element EDc by only the first connection wire CWL1, by only the second connection wire CWL2, by the first connection wire CWL1 and the second connection wire CWL2, and the like. The connection relationship may be changed in various ways.

A part of the corner drive circuit DCc may be arranged in the second corner display area CDA2 of the display panel 10. The corner drive circuit DCc arranged in the second corner display area CDA2 may be a gate drive circuit GDC. The gate drive circuit GDC may include at least one thin film transistor, and provide scan signals to the corner pixel circuit PCc and the main pixel circuit PCm arranged in the corner display area CDA and the front display area FDA, respectively.

Another part of the corner drive circuit DCc may be arranged in the peripheral area PA of the display panel 10. The corner drive circuit DCc arranged in the peripheral area PA may include an emission drive circuit EMDC. The emission drive circuit EMDC may include at least one thin film transistor, and provide emission control signals to the corner pixel circuit PCc and the main pixel circuit PCm arranged in the corner display area CDA and the front display area FDA, respectively.

The emission area of the corner light-emitting element EDc arranged in the first corner display area CDA1 and the second corner display area CDA2 may constitute corner pixels. The corner pixels may have the same pixel array in the first corner display area CDA1 and the second corner display area CDA2.

The main light-emitting element EDm and the corner light-emitting element EDc may be covered by the thin film encapsulation layer 300. In some embodiments, the thin film encapsulation layer 300 may include at least one inorganic encapsulation layer and at least one organic encapsulation layer. In an embodiment, the thin film encapsulation layer 300 may include first and second inorganic encapsulation layers 310 and 330 and an organic encapsulation layer 320 disposed therebetween.

The common power supply wire VSL through which a common voltage is transmitted to the light-emitting element, and a plurality of dams DAMS, may be arranged in the peripheral area PA of the display panel 10. The dams DAMS may be provided to overlap the common power supply wire VSL. The dams DAMS may prevent an overflow of the organic encapsulation layer 320 of the thin film encapsulation layer 300, and permeation of external moisture into the corner display area CDA and the flat display area FDA.

The dams DAMS may include a first dam DAM1, a second dam DAM2, and a third dam DAM3. A groove GV may be formed between the dams DAMS. The groove GV may be an area in which at least one organic insulating layer is removed. The dams DAMS may include a plurality of organic insulating layers OLs. The first dam DAM1 and the second dam DAM2 may include the first organic insulating layer OL1, the second organic insulating layer OL2, and the third organic insulating layer OL3.

In the present embodiment, the first dam DAM1 and the second dam DAM2 may each further include an inorganic protection layer PVX arranged between the second organic insulating layer OL2 and the third organic insulating layer OL3. The inorganic protection layer PVX may have a protruding tip PT protruding in a direction toward the center of the groove GV arranged between the first dam DAM1 and the second dam DAM2. Because an organic layer or a counter electrode in the light-emitting element may be disconnected due to the protruding tip PT, a patterning of the organic layer or the count electrode may not be needed when forming the organic layer or the counter electrode so that the size of the peripheral area PA may be remarkably reduced.

In the present embodiment, the third dam DAM3 may include the first organic insulating layer OL1, the second organic insulating layer OL2, the third organic insulating layer OL3, and the fourth organic insulating layer OL4. The third dam DAM3 may further include the inorganic protection layer PVX arranged between the second organic insulating layer OL2 and the third organic insulating layer OL3. The inorganic protection layer PVX may cover the side surface of the third dam DAM3 adjacent to the edge of the substrate 100. In other words, the inorganic protection layer PVX may be provided to cover one side surface of the second organic insulating layer OL2 that is the second layer of the third dam DAM3. The inorganic protection layer PVX may contact the top surface of the substrate 100 by extending from one side surface of the second organic insulating layer OL2. Accordingly, the first inorganic encapsulation layer 310 of the thin film encapsulation layer 300 may be in direct contact with the inorganic protection layer PVX on the side surface of the third dam DAM3. The second inorganic encapsulation layer 330 may also be in direct contact with the first inorganic encapsulation layer 310 on the side surface of the third dam DAM3.

The first inorganic encapsulation layer 310 may cover the edge of the inorganic protection layer PVX on the top surface of the substrate 100, and the second inorganic encapsulation layer 330 may cover the edge of the first inorganic encapsulation layer 310 on the top surface of the substrate 100. Such a structure may effectively prevent external air from flowing into the display area. Furthermore, as the first inorganic encapsulation layer 310, the second inorganic encapsulation layer 330, and the inorganic protection layer PVX are in contact with one another on the side surface of the third dam DAM3, the size of the peripheral area PA may be remarkably reduced. As the size of the peripheral area PA is reduced, the size of the second corner display area CDA2 may be increased accordingly. As a result, the size of the display area of the display apparatus 1 may increase.

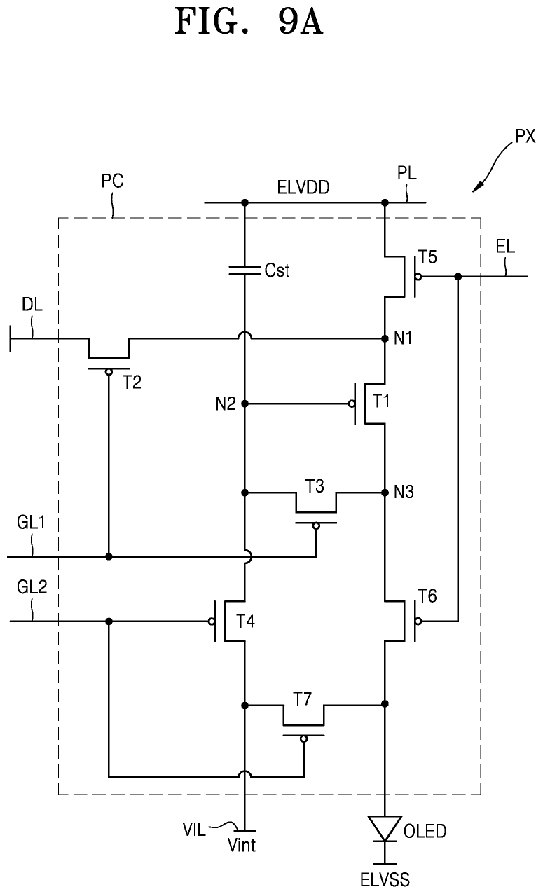

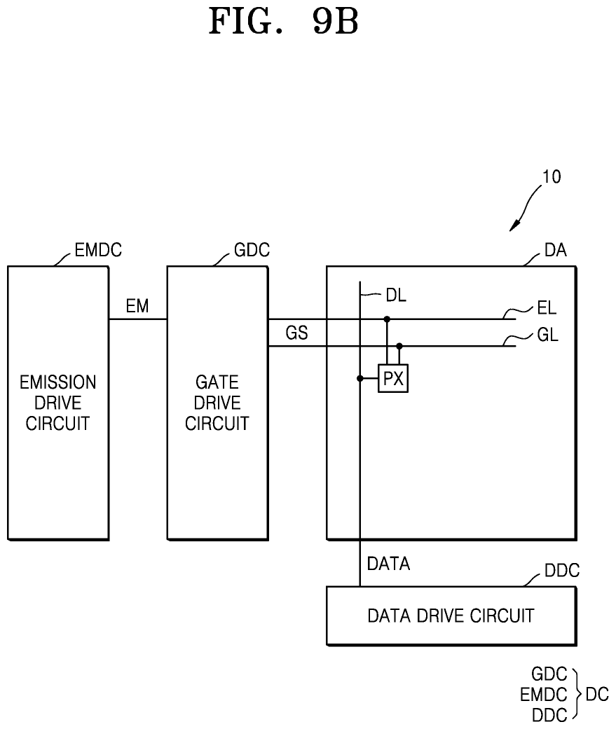

FIGS. 8A and 9A each are equivalent circuit diagrams of a pixel circuit that is applicable to a display apparatus according to an embodiment. FIGS. 8B and 9B each are schematic diagrams of the configuration of a display apparatus according to an embodiment.

Referring to FIG. 8A, a pixel PX may include the pixel circuit PC and an organic light-emitting diode OLED connected to the pixel circuit PC. The pixel circuit PC may include a first transistor T1, a second transistor T2, and a capacitor Cst. Each pixel PX may emit light, for example, red, green, blue, or white light, through the organic light-emitting diode OLED. The first transistor T1 and the second transistor T2 may each be implemented as a thin film transistor.

The second transistor T2, as a switching transistor, is connected to a gate line GL and the data line DL, and may transmit a data signal input through the data line DL to the first transistor T1 in response to a gate signal input through the gate line GL. The capacitor Cst is connected to the second transistor T2 and a driving voltage line PL, and may store a voltage corresponding to a difference between a voltage corresponding to the data signal received from the second transistor T2 and a driving voltage ELVDD supplied through the driving voltage line PL.

The first transistor T1, as a driving transistor, is connected between the driving voltage line PL and the organic light-emitting diode OLED, and may control a driving current flowing in the organic light-emitting diode OLED from the driving voltage line PL according to the voltage value stored in the capacitor Cst. The organic light-emitting diode OLED may emit light with a certain luminance by the driving current. A counter electrode of the organic light-emitting diode OLED may receive the common voltage ELVSS.

Referring to FIG. 8B, the pixels PX and signal lines for applying electrical signals to the pixels PX may be located in a display area DA. The signal lines for applying an electrical signal to each of the pixels PX may include a plurality of data lines DL and a plurality of gate lines GL.

A drive circuit DC for supplying signals to drive the pixels PX may be located outside the display area DA. The drive circuit DC may include the gate drive circuit GDC and a data drive circuit DDC. In an embodiment, the gate drive circuit GDC may be arranged in the peripheral area PA of FIG. 7 and/or the second corner display area CDA2 of FIG. 7, as described above. In detail, the gate drive circuit GDC may be arranged in the second corner display area CDA2, at the right side of the second side display area SDA2 of FIG. 5, and/or at the left side of the third side display area SDA3 of FIG. 5. The gate drive circuit GDC is connected to the gate lines GL, and may output a gate signal GS to the gate lines GL. The data drive circuit DDC may be arranged in a pad area. The data drive circuit DDC is connected to the data lines DL and may output a data signal DATA to the data lines DL.

Although FIG. 8A describes that the pixel circuit PC includes two transistors and one capacitor, the disclosure is not limited thereto. The number of transistors and the number of capacitors may be changed in various ways according to the design of the pixel circuit PC.

Referring to FIG. 9A, the pixel circuit PC may include the first transistor T1 that is a driving transistor and second to seventh transistors T2 to T7 that are switching transistors. According to the type of a transistor (P-type or N-type) and/or the operation conditions, a first terminal of each of the first to seventh transistors T1 to T7 may be a source terminal or a drain terminal, and a second terminal may be a terminal different from the first terminal. For example, when the first terminal is a source terminal, the second terminal may be a drain terminal. In an embodiment, the source terminal and the drain terminal may be referred to as a source electrode and a drain electrode, respectively.

The pixel circuit PC may be connected to a first gate line GL1 for transmitting a first gate signal, a second gate line GL2 for transmitting a second gate signal, an emission control line EL for transmitting an emission control signal, and the data line DL for transmitting a data signal, the driving voltage line PL for transmitting the driving voltage ELVDD, and an initialization voltage line VIL for transmitting an initialization voltage Vint.

The first transistor T1 may be connected between the driving voltage line PL and the organic light-emitting diode OLED. The first transistor T1 may be connected to the driving voltage line PL via the fifth transistor T5, and may be electrically connected to the organic light-emitting diode OLED via the sixth transistor T6. The first transistor T1 may include a gate connected to a second node N2, a first terminal connected to a first node N1, and a second terminal connected to a third node N3. The first transistor T1 may receive a data signal according to the switching operation of the second transistor T2 and supply a driving current to the organic light-emitting diode OLED.

The second transistor T2 (a data write transistor) may be connected between the data line DL and the first node N1, and may be connected to the driving voltage line PL via the fifth transistor T5. The first node N1 may be a node where the first transistor T1 is connected to the fifth transistor T5. The second transistor T2 may include a gate connected to the first gate line GL1, a first terminal connected to the data line DL, and a second terminal connected to the first node N1 (or the first terminal of the first transistor T1). The second transistor T2 may be turned on in response to a first gate signal received through the first gate line GL1 to perform a switching operation of transmitting the data signal received through the data line DL to the first node N1.

The third transistor T3 (a compensation transistor) may be connected between the second node N2 and the third node N3. The third transistor T3 may be connected to the organic light-emitting diode OLED via the sixth transistor T6. The second node N2 may be a node to which the gate of the first transistor T1 is connected, and the third node N3 may be a node to which the first transistor T1 and the sixth transistor T6 are connected. The third transistor T3 may include a gate connected to the first gate line GL1, a first terminal connected to the second node N2 (or the gate of the first transistor T1), and a second terminal connected to the third node N3 (or the second terminal of the first transistor T1). The third transistor T3 may be turned on in response to the first gate signal received through the first gate line GL1 to diode-connect the first transistor T1, thereby compensating for a threshold voltage of the first transistor T1.

The fourth transistor T4 (a first initialization transistor) may be connected between the second node N2 and an initialization voltage line VL. The fourth transistor T4 may include a gate connected to the second gate line GL2, a first terminal connected to the second node N2, and a second terminal connected to the initialization voltage line VIL. The fourth transistor T4 may be turned on in response to the second gate signal received through the second gate line GL2 to transmit the initialization voltage Vint to the gate of the first transistor T1, thereby initializing the gate voltage of the first transistor T1.

The fifth transistor T5 (a first emission control transistor) may be connected between the driving voltage line PL and the first node N1. The sixth transistor T6 (a second emission control transistor) may be connected between the third node N3 and the organic light-emitting diode OLED. The fifth transistor T5 may include a gate connected to the emission control line EL, a first terminal connected to the driving voltage line PL, and a second terminal connected to the first node N1. The sixth transistor T6 may include a gate connected to the emission control line EL, a first terminal connected to the third node N3, and a second terminal connected to the pixel electrode of the organic light-emitting diode OLED. The fifth transistor T5 and the sixth transistor T6 are simultaneously turned on in response to the emission control signal received through the emission control line EL so that a driving current flows in the organic light-emitting diode OLED.

The seventh transistor T7 (a second initialization transistor) may be connected between the organic light-emitting diode OLED and the initialization voltage line VL. The seventh transistor T7 may include a gate connected to the second gate line GL2, a first terminal connected to the second terminal of the sixth transistor T6 and the pixel electrode of the organic light-emitting diode OLED, and a second terminal connected to the initialization voltage line VIL. The seventh transistor T7 may be turned on in response to the second gate signal received through the second gate line GL2 to transmit the initialization voltage Vint to the pixel electrode of the organic light-emitting diode OLED, thereby initializing the voltage of the pixel electrode of the organic light-emitting diode OLED. In another embodiment, the gate of the seventh transistor T7 may be connected to a third gate line which is different from the second gate line GL2. The seventh transistor T7 may be omitted.

The capacitor Cst may include a first electrode connected to the second node N2 and a second electrode connected to the driving voltage line PL. The capacitor Cst may maintain a voltage applied to the gate electrode of the first transistor T1 by storing and maintaining a voltage corresponding to a difference between the voltages supplied to the first electrode and the second electrode.

The organic light-emitting diode OLED may include a pixel electrode, for example, an anode, and a counter electrode, for example, a cathode, facing the pixel electrode, and the counter electrode may receive the common voltage ELVSS. The organic light-emitting diode OLED may receive, from the first transistor T1, a driving current corresponding to the voltage value stored in the capacitor Cst and emit light of a certain color, thereby displaying an image.

Referring to FIG. 9B, the pixels PX and signal lines through which electronic signals may be applied to the pixels PX may be located in the display area DA. The signal lines through which electrical signals may be applied to the respective pixels PX may include the data lines DL, the gate lines GL, and the emission control lines EL.

The drive circuit DC for providing signals to drive the pixels PX may be located outside the display area DA. The drive circuit DC may include the gate drive circuit GDC, the emission drive circuit EMDC, and the data drive circuit DDC. In an embodiment, the gate drive circuit GDC may be arranged in the peripheral area PA of FIG. 7 and/or the second corner display area CDA2 of FIG. 7, as described above. In detail, the gate drive circuit GDC may be arranged in the second corner display area CDA2, at the right side of the second side display area SDA2 of FIG. 5, and/or at the left side of the third side display area SDA3 of FIG. 5. The emission drive circuit EMDC may be arranged in the peripheral area PA and an outside the gate drive circuit GDC. The data drive circuit DDC may be arranged in the pad area. The gate drive circuit GDC may be connected to the gate lines GL, and may output the gate signal GS to the gate lines GL. The emission drive circuit EMDC may be connected to the emission control lines EL, and may output an emission control signal EM through the emission control lines EL. The data drive circuit DDC may be connected to the data lines DL, and may output the data signal DATA through the data lines DL.

Although FIGS. 9A and 9B illustrate that the transistors of the pixel circuit PC are P-type transistors, the disclosure is not limited thereto. Various embodiments may be possible, for example, all transistors of the pixel circuit PC are N-type transistor, some transistors are P-type transistors and other transistors are N-type transistors, or the like.

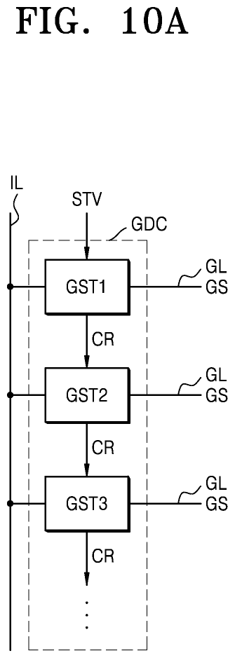

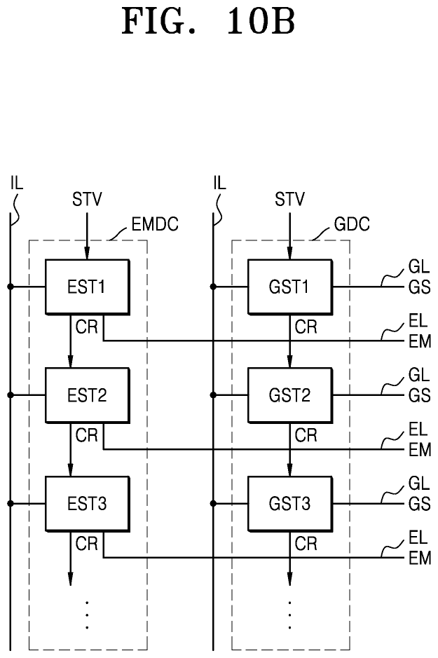

FIGS. 10A and 10B are schematic diagrams of a drive circuit according to an embodiment.

Referring to FIG. 10A, the gate drive circuit GDC may be implemented as a shift register including the stages GST1, GST2, GST3, . . . . Each of the stages GST1, GST2, GST3, . . . may be a sub-drive circuit SDC. Each of the stages GST1, GST2, GST3, . . . may be connected to the corresponding gate line GL, and may output the gate signal GS to the corresponding gate line GL. A first stage GST1 may output the gate signal GS in response to an external start signal STV, and each of the other stages GST2, GST3, . . . , other than the first stage GST1, may receive, as a start signal, a carry signal CR output from the previous stage. Each of the stages GST1, GST2, GST3, . . . may be connected to a plurality of input lines IL arranged outside the stages GST1, GST2, GST3.

In an embodiment, the drive circuit DC may include a plurality of drive circuits. For example, the drive circuit DC may include the gate drive circuit GDC and the emission drive circuit EMDC. Some of the input lines IL connected to the gate drive circuit GDC may be configured to input the same signal as some of the input lines IL connected to the emission drive circuit EMDC.

Referring to FIG. 10B, the gate drive circuit GDC may be implemented as a shift register including the stages GST1, GST2, GST3, . . . . . Each of the stages GST1, GST2, GST3, . . . may be the sub-drive circuit SDC. Each of the stages GST1, GST2, GST3, . . . may be connected to the corresponding gate line GL, and may output the gate signal GS through the corresponding gate line GL. The first stage GST1 may output the gate signal GS in response to the external start signal STV, and each of the other stages GST2, GST3, . . . , other than the first stage GST1, may receive, as a start signal, the carry signal CR output from the previous stage. Each of the stages GST1, GST2, GST3, . . . may be connected to the input lines IL arranged outside the stages GST1, GST2, GST3.

The emission drive circuit EMDC may be implemented as a shift register including a plurality of stages EST1, EST2, EST3, . . . . . Each of the stages EST1, EST2, EST3, . . . may be the sub-drive circuit SDC. Each of the stages EST1, EST2, EST3, . . . may be connected to the corresponding emission control line EL, and may output the emission control signal EM through the corresponding emission control line EL. The first stage EST1 may output the emission control signal EM in response to the external start signal STV, and each of the other stages EST2, EST3, . . . , other than the first stage EST1, may receive, as a start signal, the carry signal CR output from the previous stage. The stages EST1, EST2, EST3, . . . may be connected to the input lines IL arranged outside the stages EST1, EST2, EST3.

The input lines IL may be signal lines including a plurality of voltage lines and a plurality of clock lines. In FIG. 10A and 10B, for convenience of illustration, one input line is illustrated.

In the gate drive circuit GDC of FIGS. 10A and 10B, although each of the stages GST1, GST2, GST3, . . . is connected to one gate line GL, this is an example. Each of the stages GST1, GST2, GST3, . . . , may be connected to one or more gate lines GL, and may output the gate signals GS to the one or more gate lines GL at a preset timing.

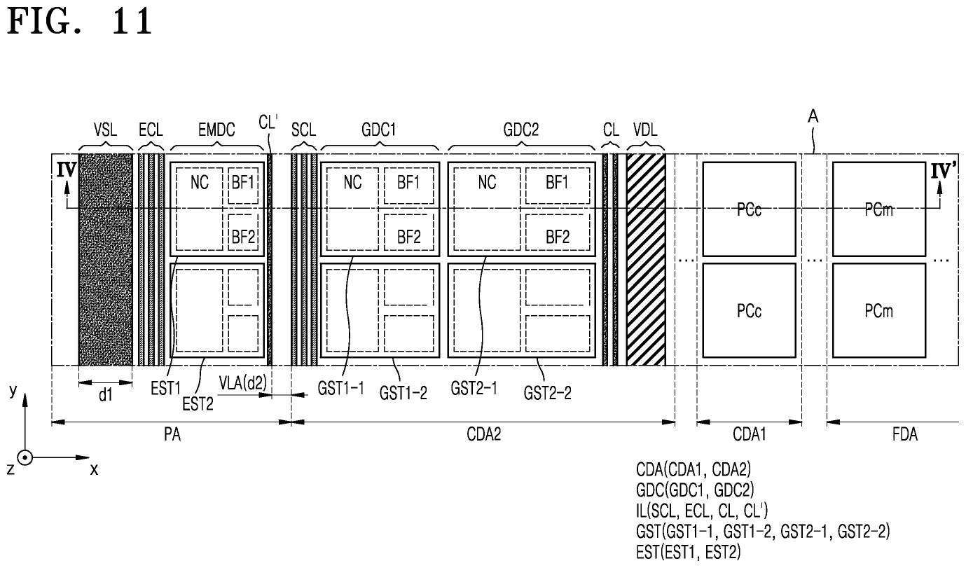

FIG. 11 is a schematic plan view of a portion of a display apparatus according to an embodiment which corresponds to an enlarged view of a region A of FIG. 6.

Referring to FIG. 11, the display panel 10 may include the front display area FDA, the corner display area CDA, and the peripheral area PA, and the corner display area CDA may include the first corner display area CDA1 and the second corner display area CDA2.

The main pixel circuits PCm may be arranged in the front display area FDA. The main pixel circuits PCm may be respectively connected to the main light-emitting elements EDm of FIG. 7 arranged in the front display area FDA and may allow the main light-emitting elements EDm to emit light. The main pixel circuits PCm may be electrically connected to the drive circuits arranged outside of the display area, and may receive electrical signals from the drive circuits.

The corner pixel circuits PCc may be arranged in the first corner display area CDA1. The corner pixel circuits PCc may be respectively connected to the corner light-emitting elements EDc of FIG. 7 arranged in the corner display area CDA and may allow the corner light-emitting element EDc to emit light. The corner pixel circuits PCc may be electrically connected to the drive circuits arranged outside of the display area, and may receive electrical signals from the drive circuits.

The gate drive circuit GDC, the input lines IL, and a driving voltage supply wire VDL may be arranged in the second corner display area CDA2. The gate drive circuit GDC may include a first gate drive circuit GDC1 and a second gate drive circuit GDC2. The gate drive circuit GDC may sequentially provide gate signals to a plurality of pixels in units of pixel rows based on the gate control signal received from a controller. In an embodiment, the first gate drive circuit GDC1 may provide a gate signal, for example, an initialization scan signal and/or a compensation scan signal, and the second gate drive circuit GDC2 may provide a gate signal, for example, a write scan signal.

The first gate drive circuit GDC1 may include initialization scan stages GST1-1 and GST1-2 to sequentially output initialization scan signals and/or compensation scan stages to sequentially output compensation scan signals. The second gate drive circuit GDC2 may include write scan stages GST2-1 and GST2-2 to sequentially output write scan signals. For example, the initialization scan stages GST1-1 and GST1-2 may sequentially output initialization scan signals to the pixels in response to initialization scan start signals and initialization scan clock signals. Likewise, the compensation scan stages may sequentially output compensation scan signals to the pixels in response to compensation scan start signals and compensation scan clock signals. The write scan stages GST2-1 and GST2-2 may sequentially output write scan signals to the pixels in response to write scan start signals and write scan clock signals.

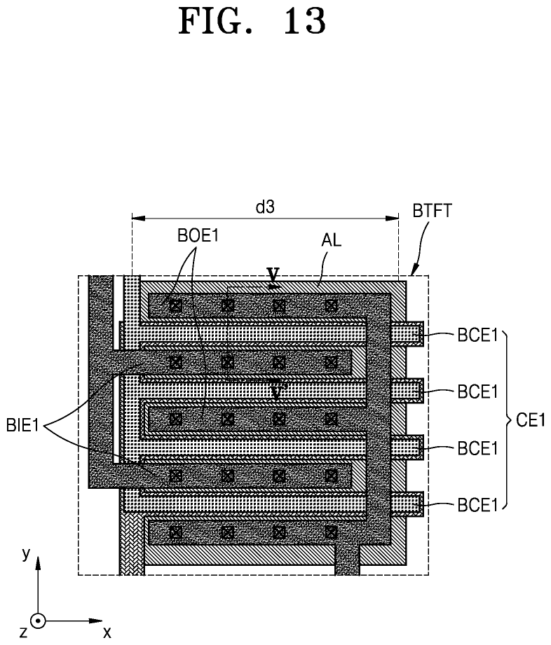

The initialization scan stages GST1-1 and GST1-2 and the write scan stages GST2-1 and GST2-2 may each include a node controller NC, a first buffer transistor BF1, and a second buffer transistor BF2. The node controller NC may include a plurality of transistors, and may control the voltage of a node by using a start signal and the like input through an input terminal. The first and second buffer transistors BF1 and BF2 are installed to isolate a signal source from a circuit driven by the signal source, and the first and second buffer transistors BF1 and BF2 are described below in detail with reference to FIG. 13.

The input lines IL arranged in the second corner display area CDA2 may include scan control wires SCL, carry wires CL, an output wire (not shown), and the like. Each of the scan stages GST may be connected to at least any one of the scan control wires SCL. Accordingly, each of the scan stages GST may generate scan signals according to the scan control signals of the scan control wires SCL. The scan control wires SCL may include a scan clock wire, a gate high voltage wire, a gate low voltage wire, and the like. The carry wires CL may include a front-end carry wire through which an output signal of a front-end stage is applied and a rear-end carry wire through which an output signal of a rear-end stage is input. The scan control wires SCL and the carry wires CL may extend in the second direction (for example, the y direction). The scan control wires SCL may be arranged between the gate drive circuit GDC and the emission drive circuit EMDC with respect to the first direction (for example, the x direction), and the carry wires CL may be arranged between the gate drive circuit GDC and the driving voltage supply wire VDL.

The driving voltage supply wire VDL arranged in the second corner display area CDA2 may be a wire configured to transmit the driving voltage ELVDD of FIG. 8A. In other words, the driving voltage supply wire VDL may be configured to transmit the driving voltage ELVDD to be applied to the driving transistors in the pixel circuits. The driving voltage supply wire VDL may extend to surround at least part of the front display area FDA, the side display area SDA, and the corner display area CDA. In detail, the driving voltage supply wire VDL may be arranged, as illustrated in FIG. 7, between the gate drive circuit GDC and the corner pixel circuit PCc.

The emission drive circuit EMDC, the input lines IL, and the common power supply wire VSL may be arranged in the peripheral area PA. The emission drive circuit EMDC may be arranged between the gate drive circuit GDC and the common power supply wire VSL.

The emission drive circuit EMDC may control light-emitting signals sequentially transmitted to a plurality of pixels in response to an emission drive circuit control signal received from the controller. The emission drive circuit EMDC may include light-emitting stages EST1 and EST2 to sequentially output light-emitting signals. For example, the light-emitting stages EST1 and EST2 may sequentially output light-emitting signals to the pixels in response to light-emitting start signals and light-emitting clock signals. Furthermore, each of the light-emitting stages EST1 and EST2 may include, like scan stages GST, the node controller NC, the first buffer transistor BF1, and the second buffer transistor BF2.

The input lines IL arranged in the peripheral area PA may include emission control wires ECL, carry wires CL′, an output wire (not shown), and the like. Each of the light-emitting stages EST may be connected to at least any one of the emission control wires ECL. Accordingly, each of the light-emitting stages EST may generate light-emitting control signals EM according to the signals through the emission control wires ECL. The emission control wires ECL may include a light-emitting clock wire, a light-emitting high voltage wire, and a light-emitting low voltage wire. The carry wires CL′ may include a front-end carry wire to which an output signal of a front-end stage is applied and a rear-end carry wire to which an output signal of a rear-end stage is input. The emission control wires ECL and the carry wires CL′ may extend in the second direction (for example, the y direction). The emission control wires ECL may be arranged between the emission drive circuit EMDC and the common power supply wire VSL with respect to the first direction (for example, the x direction), and the carry wires CL′ may be arranged between the emission drive circuit EMDC and the gate drive circuit GDC.

The common power supply wire VSL may receive the common voltage ELVSS from the controller, and supply the common voltage ELVSS to each of the main light-emitting element EDm and the corner light-emitting element EDc. The common power supply wire VSL may be arranged to surround at least part of the front display area FDA, the side display area SDA, and the corner display area CDA, and may have a loop shape with one open side. As the common power supply wire VSL extends to surround the corner display area CDA, a partial area of the common power supply wire VSL may extend in the second direction (for example, the y direction), as illustrated in FIG. 11. The common power supply wire VSL may be arranged outside the emission drive circuit EMDC with respect to the first direction (for example, the x direction). The common power supply wire VSL may have a width as large as a first distance d1.

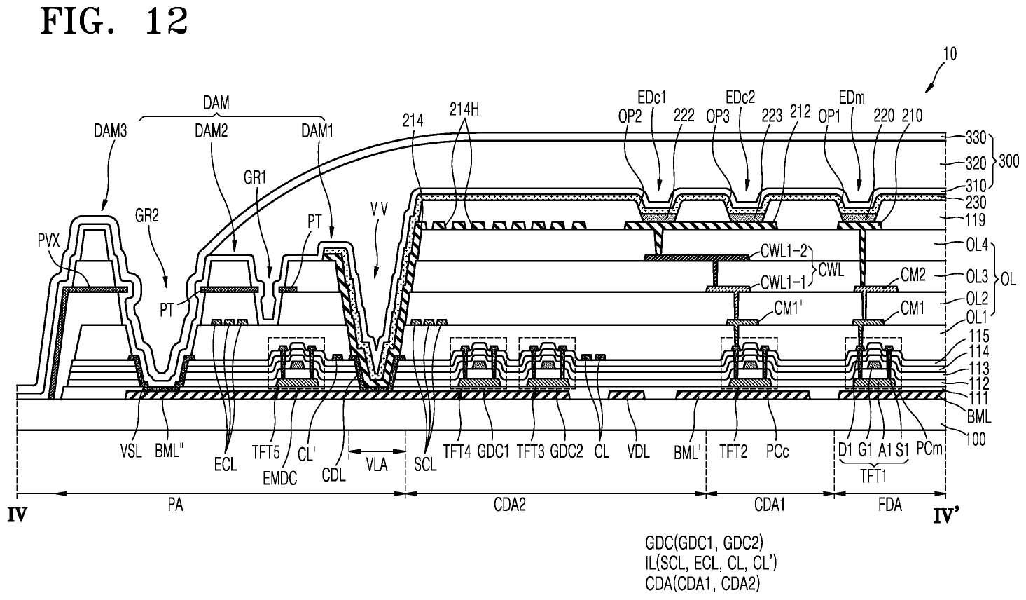

FIG. 12 is a schematic cross-sectional view of a portion of a display apparatus according to an embodiment, which corresponds to a cross-section taken along a line IV-IV′ of FIG. 11. Referring to FIG. 12, the main light-emitting element EDm and the main pixel circuit PCm connected to the main light-emitting element EDm may be arranged in the front display area FDA. The first and second corner light-emitting elements EDc1 and EDc2 may be arranged, as corner light-emitting elements, in the corner display area CDA. The first and second corner light-emitting elements EDc1 and EDc2 may include the first corner light-emitting element EDc1 and the second corner light-emitting element EDc2, which are connected to each other. The main light-emitting element EDm, the first and second corner light-emitting elements EDc1 and EDc2 may be provided as organic light-emitting diodes.

The corner pixel circuit PCc commonly connected to the first and second corner light-emitting elements EDc1 and EDc2 may be arranged in the first corner display area CDA1 of the corner display area CDA. The gate drive circuits GDC1 and GDC2 for providing driving signals, such as scan signals, to main and corner pixel circuits PCm and PCc, and the driving voltage supply wire VDL, may be arranged in the second corner display area CDA2. The main pixel circuit PCm may include a first thin film transistor TFT1, the corner pixel circuit PCc may include a second thin film transistor TFT2, the second gate drive circuit GDC2 may include a third thin film transistor TFT3, and the first gate drive circuit GDC1 may include a fourth thin film transistor TFT4.

The connection wire CWL for connecting the corner pixel circuit PCc to the first and second corner light-emitting elements EDc1 and EDc2 may be arranged in the first corner display area CDA1 and the second corner display area CDA2. The connection wire CWL may include a first connection wire CWL1-1 and a second connection wire CWL1-2, which are arranged on different layers.

The emission drive circuit EMDC for providing driving signals, such as light-emitting signals, to the main and corner pixel circuits PCm and PCc, the common power supply wire VSL, and the dams DAMS may be arranged in the peripheral area PA. The emission drive circuit EMDC may include a fifth thin film transistor TFT5.

The substrate 100 may include an insulating material, such as glass, quartz, polymer resin, and the like. The substrate 100 may be a rigid substrate or a flexible substrate capable of bending, folding, rolling, and the like.

A lower conductive layer BML may be disposed on the substrate 100. The lower conductive layer BML may include a first-1 lower conductive layer BML, a first-2 lower conductive layer BML′, and a second lower conductive layer BML″. The first-1 lower conductive layer BML may be arranged to correspond to a lower portion of the first thin film transistor TFT1 of the main pixel circuit PCm, the first-2 lower conductive layer BML′ may be arranged to correspond to a lower portion of the second thin film transistor TFT2 of the corner pixel circuit PCc, and the second lower conductive layer BML″ may be arranged to correspond to a lower portion of the gate and emission drive circuits GDC and EMDC. The first-1 lower conductive layer BML, the first-2 lower conductive layer BML′, and the second lower conductive layer BML″ may be disposed on the same plane, for example, on the substrate 100.

The first-1, first-2, and second lower conductive layers BML, BML′, and BML″ may be provided between the substrate 100 and a buffer layer 111. In detail, the first-1, first-2, and second lower conductive layers BML, BML′, and BML″ may be arranged between the substrate 100 and the main and corner pixel circuits PCm and PCc and/or between the substrate 100 and the gate and emission drive circuits GDC and EMDC. For example, the first-1 lower conductive layer BML may be arranged between the substrate 100 and the buffer layer 111 in the front display area FDA, and may overlap a first semiconductor layer A1 of the first thin film transistor TFT1. The first-2 lower conductive layer BML′ may be arranged between the substrate 100 and the buffer layer 111 in the first corner display area CDA1 and/or the second corner display area CDA2, and may overlap a semiconductor layer of the second thin film transistor TFT2. The second lower conductive layer BML″ may be arranged between the substrate 100 and the buffer layer 111 in the second corner display area CDA2 and/or the peripheral area PA, and may overlap semiconductor layers of the third to fifth thin film transistors TFT3, TFT4, and TFT5. The second lower conductive layer BML″ not only may be arranged to overlap the gate drive circuit GDC and the emission drive circuit EMDC, but also may extend to the outer edge to overlap the common power supply wire VSL.

The lower conductive layers BML, BML′, and BML″ may prevent external light from reaching the thin film transistor and deterioration of performance of the thin film transistor by the externally input or reflected light. In some embodiments, as a constant voltage or signal is applied to the first-1, first-2, and second lower conductive layers BML, BML′, and BML″, the first-1, first-2, and second lower conductive layers BML, BML′, and BML″ may function to prevent damage of the pixel circuit by electrostatic discharge. In particular, as it is described below in detail, the second lower conductive layer BML″ contacts the common power supply wire VSL so that the voltage drop of the common voltage ELVSS may be reduced.

Accordingly, the first-1, first-2, and second lower conductive layers BML, BML′, and BML″ may include a conductive material, and also include a light blocking material, for example, black ink or dye. In detail, the first-1, first-2, and second lower conductive layers BML, BML′, and BML″ may each include a metal material, such as aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may have a single layer or multilayer structure including the materials described above. However, the disclosure is not limited thereto, and the first-1, first-2, and second lower conductive layers BML, BML′, and BML″ may include a transparent conductive material. For example, the first-1, first-2, and second lower conductive layers BML, BML′, and BML″ may each include a conductive oxide, such as an indium tin oxide (ITO), an indium zinc oxide (IZO), a zinc oxide (ZnO), an indium oxide (In₂O₃), an indium gallium oxide (IGO), or an aluminum zinc oxide (AZO).

The buffer layer 111 may be located on the substrate 100, may reduce or block permeation of foreign materials, such as moisture or external air, from under the substrate 100, and may provide a planarized surface on the substrate 100. The buffer layer 111 may include an inorganic material, such as oxide or nitride, or an organic material, or an organic/inorganic complex, and may have a single layer or multilayer structure of an inorganic material and an organic material. A barrier layer (not shown) for blocking permeation of external air may be further included between the substrate 100 and the buffer layer 111. In some embodiments, the buffer layer 111 may include a silicon oxide (SiO₂) or a silicon nitride (SiNₓ).

The first thin film transistor TFT1, the second thin film transistor TFT2, the third thin film transistor TFT3 may be disposed on the buffer layer 111. The first thin film transistor TFT1 may be connected to the main light-emitting element EDm to drive the main light-emitting element EDm. The second thin film transistor TFT2 may be connected to the first and second corner light-emitting elements EDc1 and EDc2 to drive the first and second corner light-emitting elements EDc1 and EDc2. The third thin film transistor TFT3 and the fourth thin film transistor TFT4 may provide driving signals such as scan signals to the thin film transistor in the gate drive circuit GDC. The fifth thin film transistor TFT5 may provide a driving signal such as a light-emitting signal to the thin film transistor in the emission drive circuit EMDC.

The second thin film transistor TFT2, the third thin film transistor TFT3, the fourth thin film transistor TFT4, and the fifth thin film transistor TFT5 may have a configuration similar to that of the first thin film transistor TFT1, and thus, the description of the first thin film transistor TFT1 replaces those of the second thin film transistor TFT2 and the third thin film transistor TFT3. The first thin film transistor TFT1 may include the first semiconductor layer A1, a first gate electrode G1, a first source electrode S1, and a first drain electrode D1.

The first semiconductor layer A1 may be disposed on the buffer layer 111, and may include polysilicon. In another embodiment, the first semiconductor layer A1 may include amorphous silicon. In another embodiment, the first semiconductor layer A1 may include an oxide of at least one or more material selected from the group consisting of indium (In), gallium (Ga), stannum (Sn), zirconium (Zr), vanadium (V), hafnium (Hf), cadmium (Cd), germanium (Ge), Cr, Ti, and zinc (Zn). The first semiconductor layer A1 may include a channel region, and a source region and a drain region doped with impurities.

A first gate insulating layer 112 may be provided to cover the first semiconductor layer A1. The first gate insulating layer 112 may include an inorganic insulating material, such as a silicon oxide (SiO₂), a silicon nitride (SiNₓ), a silicon oxynitride (SiOₓN_{y}), an aluminum oxide (Al₂O₃), a titanium oxide (TiO₂), a tantalum oxide (Ta₂O₅), a hafnium oxide (HfO₂), and the like. The first gate insulating layer 112 may be a single layer or multilayer including the inorganic insulating material described above.

The first gate electrode G1 may be disposed on the first gate insulating layer 112 to overlap the first semiconductor layer A1. The first gate electrode G1 may include Mo, Al, Cu, Ti, and/or the like, and may be formed of a single layer or multilayer. As an example, the first gate electrode G1 may be a single layer of Mo.

The second gate insulating layer 113 may be provided to cover the first gate electrode G1. The second gate insulating layer 113 may include an inorganic insulating material, such as SiO₂, SiNₓ, SiOₓN_{y}, Al₂O₃, TiO₂, Ta₂O₅, HfO₂, a zinc oxide (ZnO₂), or the like. The second gate insulating layer 113 may be a single layer or multilayer including the inorganic insulating material described above.

A second gate layer (not shown) may be disposed on the second gate insulating layer 113. The second gate layer may be used as a wire for transmitting a signal or as a capacitor electrode. The second gate layer may include Al, Pt, Pd, Ag, Mg, Au, Ni, Nd, Ir, Cr, Ca, Mo, Ti, W, and/or Cu, and may be a single layer or multilayer including the material described above.

A first interlayer insulating layer 114 may be disposed on the second gate insulating layer 113 to cover the second gate layer (not shown). The first interlayer insulating layer 114 may include SiO₂, SiNₓ, SiOₓN_{y}, Al₂O₃, TiO₂, Ta₂O₅, HfO₂, and the like. The first interlayer insulating layer 114 may be a single layer or multilayer including the inorganic insulating material described above.

A third gate layer (not shown) may be disposed on the first interlayer insulating layer 114. The third gate layer may be used as a wire for transmitting a signal or as a capacitor electrode. The third gate layer may include Al, Pt, Pd, Ag, Mg, Au, Ni, Nd, Ir, Cr, Ca, Mo, Ti, W, and/or Cu, and may be a single layer or multilayer including the material described above.

A second interlayer insulating layer 115 may be disposed on the first interlayer insulating layer 114 to cover the third gate layer (not shown). The first interlayer insulating layer 114 may include SiO₂, SiNₓ, SiOₓN_{y}, Al₂O₃, TiO₂, Ta₂O₅, HfO₂, and the like. The second interlayer insulating layer 115 may be a single layer or multilayer including the inorganic insulating material described above.

The first source electrode S1 and the first drain electrode D1 may be disposed on the second interlayer insulating layer 115. The first source electrode S1 and the first drain electrode D1 may each include a conductive material including Mo, Al, Cu, Ti, and/or the like, and may each be formed in a multilayer or single layer including the materials described above. As an example, the first source electrode S1 and the first drain electrode D1 may each have a multilayer structure of Ti/Al/Ti.

The first organic insulating layer OL1 may be disposed on the second interlayer insulating layer 115 to cover the first source electrode S1 and the first drain electrode D1. First connection electrodes CM1 and CM1′ respectively connected to the main and corner pixel circuits PCm and PCc may be disposed on the first organic insulating layer OL1. The first connection electrodes CM1 and CM1′ may each include a conductive material including Mo, Al, Cu, Ti, and/or the like, and may each be formed in a multilayer or single layer including the materials described above.

The second organic insulating layer OL2 may be disposed on the first organic insulating layer OL1 to cover the first connection electrodes CM1 and CM1′. The first connection wire CWL1-1 and a second connection electrode CM2 may be disposed on the second organic insulating layer OL2. The first connection wire CWL1-1 may be connected to the first connection electrode CM1′ which is connected to the corner pixel circuit PCc, and the second connection electrode CM2 may be connected to the first connection electrode CM1 which is connected to the main pixel circuit PCm.

The first connection wire CWL1-1 and the second connection electrode CM2 may each include a conductive material including Mo, Al, Cu, Ti, and/or the like, and may each be formed in a multilayer or single layer including the materials described above. Alternatively, the first connection wire CWL1-1 and the second connection electrode CM2 may each include a transparent conductive material. For example, the first connection wire CWL1-1 and the second connection electrode CM2 may each include a transparent conducting oxide (TCO). The first connection wire CWL1-1 and the second connection electrode CM2 may each include a conductive oxide, such as ITO, IZO, ZnO, In₂O₃, IGO, or AZO.

The third organic insulating layer OL3 may be disposed on second organic insulating layer OL2 to cover the first connection wire CWL1-1 and the second connection electrode CM2. The second connection wire CWL1-2 may be disposed on the third organic insulating layer OL3. The second connection wire CWL1-2 may be connected to the first connection wire CWL1-1 through a contact hole formed through the third organic insulating layer OL3.

The second connection wire CWL1-2 may include a conductive material including Mo, Al, Cu, Ti, or the like, and may be formed in a multilayer or single layer including the materials described above. Alternatively, the second connection wire CWL1-2 may include a transparent conductive material. For example, the second connection wire CWL1-2 may include TCO. The second connection wire CWL2 may include a conductive oxide, such as ITO, IZO, ZnO, In₂O₃, IGO, or AZO.

At least one of the first connection wire CWL1-1 and the second connection wire CWL1-2 extend from the first corner display area CDA1 to the second corner display area CDA2. Accordingly, partial areas of the first connection wire CWL1-1 and the second connection wire CWL1-2 extending to the second corner display area CDA2 may overlap the driving voltage supply wire VDL and/or the gate drive circuits GDC1 and GDC2.

The fourth organic insulating layer OL4 may be arranged on the third organic insulating layer OL3 to cover the second connection wire CWL1-2. The fourth organic insulating layer OLA may have a flat upper surface so that a first pixel electrode 210 and a second pixel electrode 212 arranged thereon are formed to be flat.

The first organic insulating layer OL1, the second organic insulating layer OL2, the third organic insulating layer OL3, and the fourth organic insulating layer OL4, as described above, may include general purpose polymers, such as benzocyclobutene (BCB), polyimide, hexamethyldisiloxane (HMDSO), polymethylmethacrylate (PMMA), or polystyrene, a polymer derivative having a phenolic group, acrylic polymer, imide-based polymer, aryl ether-based polymer, amide-based polymer, fluorine-based polymer, p-xylene-based polymer, vinyl alcohol-based polymer, or the like. The first organic insulating layer OL1, the second organic insulating layer OL2, the third organic insulating layer OL3, and the fourth organic insulating layer OL4 may be modified in various ways, for example, the organic insulating layer may include the same material, different materials, or the like.

The main, first corner, and second corner light-emitting elements EDm, EDc1, and EDc2 may be disposed on the fourth organic insulating layer OL4. The main light-emitting element EDm may include the first pixel electrode 210, a first emission layer 220, and a counter electrode 230. The first corner light-emitting element EDc1 may include the second pixel electrode 212, a second emission layer 222, and the counter electrode 230, and the second corner light-emitting element EDc2 may include the second pixel electrode 212, a third emission layer 223, and the counter electrode 230. The first corner light-emitting element EDc1 and the second corner light-emitting element EDc2 may share the second pixel electrode 212.

The first pixel electrode 210 and the second pixel electrode 212 may each include a conductive oxide, such as ITO, IZO, ZnO, In₂O₃, IGO, or AZO. The first pixel electrode 210 and the second pixel electrode 212 may include a reflective film including Ag, Mg, Al, Pt, Pd, Au, Ni, Nd, Ir, Cr, or a compound thereof. For example, the first pixel electrode 210 and the second pixel electrode 212 may each have a structure in which films including ITO, IZO, ZnO, or In₂O₃ are formed above/below the reflective film described above. In this case, the first pixel electrode 210 and the second pixel electrode 212 may each have a stack structure of ITO/Ag/ITO.

A pixel defining layer 119 may be disposed on the fourth organic insulating layer OL4, and may define emission area of the main, first corner, and second corner light-emitting elements EDm, EDc1, and EDc2. The pixel defining layer 119 may cover an edge of the first pixel electrode 210, and may include a first opening OP1 for exposing the central portion of the first pixel electrode 210. The first opening OP1 may define the size and shape of the emission area of the main light-emitting element EDm.

The pixel defining layer 119 may include a second opening OP2 and a third opening OP3 which cover edges of the second pixel electrode 212 and expose two areas of the central portion of the second pixel electrode 212. The second opening OP2 may define the emission area of the first corner light-emitting element EDc1, and the third opening OP3 may define an emission area of the second corner light-emitting element EDc2. In some embodiments, the second opening OP2 and the third opening OP3 may have the same size and shape.

The pixel defining layer 119 may increase a distance between the edges of the first and second pixel electrodes 210 and 212 and the counter electrode 230 arranged above the first and second pixel electrodes 210 and 212 so that generation of arc at the edges of the first and second pixel electrodes 210 and 212 may be prevented. The pixel defining layer 119 may be formed of an organic insulating material, such as polyimide, polyamide, acryl resin, benzocyclobutene, HMDSO, phenol resin, and the like, by a method such as spin coating and the like.

The first emission layer 220, the second emission layer 222, and the third emission layer 223 may be arranged in the first opening OP1, the second opening OP2, and the third opening OP3 of the pixel defining layer 119, respectively. The first emission layer 220, the second emission layer 222, and the third emission layer 223 may each include a polymer material or a low molecular weight material, and emit red, green, blue, or white light. In an embodiment, the second emission layer 222 and the third emission layer 223 may include the same material, and emit light of the same color.

An organic function layer (not shown) may be disposed above and/or below the first emission layer 220, the second emission layer 222, and the third emission layer 223. The organic function layers of the first emission layer 220, the second emission layer 222, and the third emission layer 223 may include a hole injection layer (HIL), a hole transport layer (HTL), an electron transport layer (ETL), and/or an electron injection layer (EIL). The organic function layers may be integrally formed to correspond to the light-emitting elements in the front display area FDA and the corner display area CDA.

The counter electrode 230 may be disposed on the first emission layer 220, the second emission layer 222, and the third emission layer 223. The counter electrode 230 may include a conductive material having a low work function. For example, the counter electrode 230 may include a (semi-)transparent layer including Ag, Mg, Al, Pt, Pd, Au, Ni, Nd, Ir, Cr, Li, Ca, an alloy thereof, or the like. Alternatively, the counter electrode 230 may further include a layer, such as ITO, IZO, ZnO, or In₂O₃, on the (semi-)transparent layer including the material described above. The counter electrode 230 may be integrally formed to correspond to the main, first corner, and second corner light-emitting elements EDm, EDc1, and EDc2 in the front display area FDA and the corner display area CDA.

An upper layer (not shown) including an organic material may be formed on the counter electrode 230. The upper layer may be provided to protect the counter electrode 230 and simultaneously increase light extraction efficiency. The upper layer may include an organic material having a refractive index higher than that of the counter electrode 230. Alternatively, the upper layer may include layers with different refractive indexes. For example, the upper layer may include a high refractive index layer, a low refractive index layer and a high refractive index layer sequentially stacked on the counter electrode 230.

The thin film encapsulation layer 300 may be disposed on the counter electrode 230 and/or the upper layer. The thin film encapsulation layer 300 may cover the main, first corner, and second corner light-emitting elements EDm, EDc1, and EDc2, and prevent the main, first corner, and second corner light-emitting elements EDm, EDc1, and EDc2 from being damaged by external moisture, oxygen, or like. The thin film encapsulation layer 300 may cover the front display area FDA, and extend from the front display area FDA to the peripheral area PA. The thin film encapsulation layer 300 may include at least one inorganic encapsulation layer and at least one organic encapsulation layer. FIG. 12 illustrates, as an example, that the thin film encapsulation layer 300 includes the first inorganic encapsulation layer 310, the organic encapsulation layer 320 and the second inorganic encapsulation layer 330.

The first inorganic encapsulation layer 310 may cover the counter electrode 230, and include SiO₂, SiNₓ, SiOₓN_{y}, and/or the like. As the first inorganic encapsulation layer 310 is formed along a structure thereunder, an upper surface thereof may not be flat. The organic encapsulation layer 320 may cover the first inorganic encapsulation layer 310, and unlike the first inorganic encapsulation layer 310, may have an upper surface that is approximately flat. In detail, the upper surface of the organic encapsulation layer 320 may be approximately flat in a portion corresponding to the front display area FDA and the first and second corner display areas CDA1 and CDA2. The organic encapsulation layer 320 may include a polymer-based material. The polymer-based material may include acrylic resin, epoxy-based resin, polyimide, polyethylene, and the like. The acrylic resin may include, for example, polymethylmethacrylate, polyacrylic acid, and the like. The organic encapsulation layer 320 may be transparent. The second inorganic encapsulation layer 330 may cover the organic encapsulation layer 320, and include SiO₂, SiNₓ, SiOₓN_{y}, and/or the like. The first and second inorganic encapsulation layers 310 and 330 may be formed by a chemical vapor deposition (CVD) method, and the organic encapsulation layer 320 may be formed through a process in which an organic material in a liquid form is coated on the substrate 100 and then hardened.

Referring to the first corner display area CDA1 of FIG. 12, the first-2 lower conductive layer BML′ may be disposed on the substrate 100. The first-2 lower conductive layer BML′ may be disposed to correspond to a lower portion of the corner pixel circuit PCc, as described above.

The corner pixel circuit PCc may be arranged in the first corner display area CDA1, and one corner pixel circuit PCc may be connected to at least two corner light-emitting elements, that is, the first and second corner light-emitting elements EDc1 and EDc2. For example, one corner pixel circuit PCc may be connected to the first corner light-emitting element EDc1 and the second corner light-emitting element EDc2. Although, in the drawings, one corner pixel circuit PCc is connected to two corner light-emitting elements, the disclosure is not limited thereto. Various modifications thereof may be possible, for example, one corner pixel circuit PCc may be connected to three to four corner light-emitting elements, and the like.

The corner pixel circuit PCc may be connected to the first and second corner light-emitting elements EDc1 and EDc2 through the connection wire CWL extending from the first corner display area CDA1 to the second corner display area CDA2. The connection wire CWL may include the first connection wire CWL1-1 arranged on the second organic insulating layer OL2 and the second connection wire CWL1-2 arranged on the third organic insulating layer OL3. The second connection wire CWL1-2 may be connected to the first connection wire CWL1-1 through a contact hole formed through the third organic insulating layer OL3. The first connection wire CWL1-1 may be connected the first connection electrode CM1′ connected to the corner pixel circuit PCc through the contact hole, and as the second connection wire CWL1-2 is connected to the second pixel electrode 212 through the contact hole. The corner pixel circuit PCc may be connected to the first and second corner light-emitting elements EDc1 and EDc2 through the first connection electrode CM1′ and the connection wire CWL.

Referring to the second corner display area CDA2 of FIG. 12, the second lower conductive layer BML″ and the driving voltage supply wire VDL may be disposed on the substrate 100. The second lower conductive layer BML″ may be disposed to correspond to a lower portion of the gate drive circuit GDC, as described above. The driving voltage supply wire VDL, as a wire for transmitting the driving voltage ELVDD of FIG. 8A, may include the same material as those of the first-1, first-2, and second lower conductive layers BML, BML′, and BML″, and may be disposed on the same layer.

The second lower conductive layer BML″ and the driving voltage supply wire VDL may be covered by the buffer layer 111, and the gate drive circuit GDC may be disposed on the buffer layer 111. The gate drive circuit GDC may include, as described above, the first gate drive circuit GDC1 and the second gate drive circuit GDC2. In an embodiment, the first gate drive circuit GDC1 may provide a gate signal, for example, an initialization scan signal and/or a compensation scan signal, and the second gate drive circuit GDC2 may provide a gate signal, for example, a write scan signal. The third thin film transistor TFT3 and the fourth thin film transistor TFT4 in the gate drive circuit GDC may include substantially the same structure as the structure described above in the first thin film transistor TFT1.

The input lines IL may be disposed on the second corner display area CDA2. The input lines IL arranged in second corner display area CDA2 may include the scan control wires SCL and the carry wires CL. As described above in FIG. 11, a scan control signal may be transmitted to the gate drive circuit GDC through the scan control wires SCL, and the output signals of the front-/rear-end stages may be transmitted through the carry wires CL. The carry wires CL may be arranged between the second interlayer insulating layer 115 and the first organic insulating layer OL1, may include the same material as those of the first source electrode S1 and/or the first drain electrode D1 of the first thin film transistor TFT1, and may be disposed on substantially the same layer. The scan control wires SCL may be arranged between the first organic insulating layer OL1 and the second organic insulating layer OL2, may include the same material as those of the first connection electrodes CM1 and CM1′, and may be disposed on substantially the same layer.

A power supply electrode layer 214 may be disposed on the organic insulating layer OL arranged in the second corner display area CDA2. The power supply electrode layer 214 may contact a wire for transmitting the common voltage ELVSS of FIG. 8A in a large area, thereby reducing contact resistance of the power supply electrode layer 214 and the wire for transmitting the common voltage ELVSS, and thus, the voltage drop of the common voltage ELVSS transmitted by the power supply electrode layer 214 may be reduced. The power supply electrode layer 214 may include the same material as those of the first pixel electrode 210 and the second pixel electrode 212, and may be disposed on substantially the same layer. In other words, the power supply electrode layer 214 may include a conductive oxide, such as ITO, IZO, ZnO, In₂O₃, IGO, or AZO. The power supply electrode layer 214 may include a reflective film including Ag, Mg, Al, Pt, Pd, Au, Ni, Nd, Ir, Cr, or a compound thereof. For example, the power supply electrode layer 214 may have a structure of films including ITO, IZO, ZnO, or In₂O₃ and disposed above/below the reflective film described above. In this case, the power supply electrode layer 214 may have a stack structure of ITO/Ag/ITO.

The power supply electrode layer 214 may include a plurality of first holes 214H. In an embodiment, an area of the power supply electrode layer 214, which is arranged on the fourth organic insulating layer OLA and overlapping the gate drive circuit GDC, may include a plurality of first holes 214H. The first holes 214H of the power supply electrode layer 214 may provide a path through which the materials included in the organic insulating layer OL arranged below the power supply electrode layer 214 are vaporized and discharged to the outside. After forming the pixel defining layer 119 on the first pixel electrode 210, the second pixel electrode 212, and the power supply electrode layer 214, a thermal process (for example, curing process) is performed, a part of the material in the first to fourth organic insulating layers OL1, OL2, OL3, and OL4 disposed below the power supply electrode layer 214 is vaporized by the heat applied during the thermal process and may be discharged to the outside through the first holes 214H. Accordingly, when the power supply electrode layer 214 does not include the first holes 214H, a gas generated from the organic insulating layer OL is moved toward the main, first corner, and second corner light-emitting elements EDm, EDc1, and EDc2 and affects the main, first corner, and second corner light-emitting elements EDm, EDc1, and EDc2, so that light is not emitted from the main, first corner, and second corner light-emitting elements EDm, EDc1, and EDc2. Accordingly, as the power supply electrode layer 214 includes the first holes 214H, the main, first corner, and second corner light-emitting elements EDm, EDc1, and EDc2 may have improved reliability and a lower defective rate.

Next, referring to the peripheral area PA of FIG. 12, the second lower conductive layer BML″ may be disposed on the substrate 100. The second lower conductive layer BML″ arranged in peripheral area PA may extend to the second corner display area CDA2. In other words, the second lower conductive layer BML″ may be arranged to correspond to a lower portion of the emission drive circuit EMDC, as described above. The second lower conductive layer BML″ may include the same materials as those of the first-1 and first-2 lower conductive layers BML and BML′, and may be disposed on substantially the same layer.

The second lower conductive layer BML″ may be covered with the buffer layer 111, and the emission drive circuit EMDC may be disposed on the buffer layer 111. The emission drive circuit EMDC may provide a light-emitting signal to a plurality of pixels. The fifth thin film transistor TFT5 in the emission drive circuit EMDC may have substantially the same structure as the structure described above in the first thin film transistor TFT1.

The input lines IL may be arranged in peripheral area PA. The input lines IL arranged in the peripheral area PA may include the emission control wires ECL and the carry wires CL′. As described above with reference to FIG. 11, the emission control wires ECL may be configured to transmit an emission control signal to the emission drive circuit EMDC, and the carry wires CL′ may be configured to transmit output signals of the front-/rear-end stages. I The carry wires CL′ may be arranged between the second interlayer insulating layer 115 and the first organic insulating layer OL1, may include the same material as those of the first source electrode S1 and/or the first drain electrode DI of the first thin film transistor TFT1, and may be disposed on substantially the same layer. The emission control wires ECL may be arranged between the first organic insulating layer OL1 and the second organic insulating layer OL2, may include the same material as those of the first connection electrodes CM1 and CM1′, and may be disposed on substantially the same layer.

Furthermore, the dams DAMS may be arranged in the peripheral area PA. The dams DAMS may prevent the overflow of the organic encapsulation layer 320 of the thin film encapsulation layer 300, and block external permeation of moisture. The dams DAMS may include the first dam DAM1, the second dam DAM2, and the third dam DAM3. The dams DAMS may be provided by stacking the organic insulating layers OLs. The first dam DAM1 and the second dam DAM2 may each include the first organic insulating layer OL1, the second organic insulating layer OL2, and the third organic insulating layer OL3. The third dam DAM3 may include the first to fourth organic insulating layers OL1, OL2, OL3, and OL4.

First and second grooves GR1 and GR2 concave in the depth direction may be formed between the dams DAMS. The first groove GR1 from which the second organic insulating layer OL2 and the third organic insulating layer OL3 are removed may be formed between the first dam DAM1 and the second dam DAM2. The second groove GR2 from which the first organic insulating layer OL1, the second organic insulating layer OL2, and the third organic insulating layer OL3 are removed may be formed between the second dam DAM2 and the third dam DAM3.

The first dam DAM1, the second dam DAM2, and the third dam DAM3 may further include the inorganic protection layer PVX disposed between the second organic insulating layer OL2 and the third organic insulating layer OL3. The inorganic protection layer PVX may have the protruding tip PT protruding in a direction toward the center of the groove GV arranged between the first dam DAM1 and the second dam DAM2. Because the organic layer or the counter electrode in the light-emitting element is disconnected due to the protruding tip PT, the organic layer or the counter electrode may be formed without patterning so that the size of the peripheral area PA may be remarkably reduced. Furthermore, the inorganic protection layer PVX may cover the side surface of the third dam DAM3, so that the inorganic protection layer PVX, the first inorganic encapsulation layer 310, and the second inorganic encapsulation layer 330 may cover the third dam DAM3. As the structure as above may function to prevent contaminants, such as moisture or external air, from permeating into the display area, the size of the peripheral area PA may be remarkably reduced. As the size of the peripheral area PA is reduced, the size of the second corner display area CDA2 may be increased accordingly, which may mean that the size of the display area of the display apparatus 1 is increased.

The power supply electrode layer 214 may extend from the second corner display area CDA2 to the peripheral area PA. In other words, the power supply electrode layer 214 may be arranged on the fourth organic insulating layer OL4 arranged in the second corner display area CDA2, and may extend to an upper portion of the first dam DAM1 arranged in the peripheral area PA by passing through a via valley VV to be described below. However, the power supply electrode layer 214 may extend only to a partial area of the upper portion of the first dam DAM1 due to the via valley VV. In other words, the power supply electrode layer 214 may be arranged not to overlap the emission drive circuit EMDC. In this case, as the power supply electrode layer 214 is not arranged on the dams DAMS, vaporized materials from the organic insulating layer OL may be freely discharged so that holes for discharging a gas to the outside are unnecessary. As a result, by not arranging the power supply electrode layer 214 on the emission drive circuit EMDC and the common power supply wire VSL, not only the infiltration of external contaminants along the power supply electrode layer 214 may be prevented, but also there is no need to arranged a plurality of holes, and thus, an effect of a simplified process design may be simultaneously implemented.

Furthermore, the common power supply wire VSL may be arranged on the substrate 100 and the second lower conductive layer BML″ in an area corresponding to the second groove GR2. The common power supply wire VSL, which is a power wire for receiving the common voltage ELVSS and transmitting the received common voltage ELVSS to a plurality of pixels, may be arranged in the peripheral area PA. The common power supply wire VSL may include the same material as those of the first source electrode S1 and/or the first drain electrode D1 of the first thin film transistor TFT1, and may be disposed on substantially the same layer as the first source electrode S1 and/or the first drain electrode D1 of the first thin film transistor TFT1.

The buffer layer 111, the first gate insulating layer 112, the second gate insulating layer 113, the first interlayer insulating layer 114, and the second interlayer insulating layer 115 may each include an opening in an area overlapping the second groove GR2. Accordingly, the common power supply wire VSL may be disposed on the second interlayer insulating layer 115, and may directly contact the second lower conductive layer BML″ through the openings of the insulating layers. In other words, the upper surface of a part of the second lower conductive layer BML″ overlapping the second groove GR2 may be exposed by the opening of the insulating layers, and the exposed upper surface may be in direct contact with the common power supply wire VSL deposited thereon.

When the reference line width of the common power supply wire VSL in the first direction (for example, the x direction) is assumed to be the first distance d1, the second lower conductive layer BML″ that contacts and is electrically connected to the common power supply wire VSL may secure a width much greater than the first distance d1. In detail, as illustrated in FIG. 12, as the second lower conductive layer BML″ may extend from the lower portion of the common power supply wire VSL to overlap the emission drive circuit EMDC and the gate drive circuit GDC, the second lower conductive layer BML″ may have a width much greater than the first distance d1. When the size of the second lower conductive layer BML″ electrically connected to the common power supply wire VSL is increased, the electrical resistance of a wire for transmitting the common voltage ELVSS is reduced. Accordingly, there is an effect that the voltage drop of the common voltage ELVSS may be reduced.

A common power supply wire according to the related art is in direct contact with wires arranged above a common power supply wire, and transmits a common voltage to a plurality of pixels. In detail, the common power supply wire is electrically connected to a wire disposed on the same layer (hereinafter, referred to as the second source/drain layer) as a first connection electrode while overlapping the common power supply wire, and applies the common voltage to the counter electrode disposed thereon. However, in this case, as a wire arranged on the second source/drain layer may be used in the emission drive circuit and the gate drive circuit, the wire in contact with the common power supply wire may not have a large area in the second source/drain layer. As a result, as electrical resistance needs to be reduced by increasing the width of the common power supply wire, the size of the peripheral area needs to be increased. Furthermore, as the counter electrode needs to be arranged even in an upper portion of the common power supply wire, a large peripheral are needs to be secured for the tolerance margin of the counter electrode, and holes for discharging the gas from the organic insulating layer may be arranged above the emission drive circuit.

In contrast, in the display apparatus 1 according to an embodiment, as the common power supply wire VSL contacts not the wire arranged above the common power supply wire VSL, but the second lower conductive layer BML″ arranged thereunder and transmits the common voltage ELVSS, the width of the common power supply wire VSL is reduced so that the size of the peripheral area PA may be reduced. In other words, as the second lower conductive layer BML″, unlike the second source/drain layer, may be arranged to overlap the emission drive circuit EMDC and the gate drive circuit GDC, the area of the second lower conductive layer BML″ may be sufficiently secured, and thus, when the width of the common power supply wire VSL is narrow, the electrical resistance may be reduced. In addition, in a valley area VLA arranged between the emission drive circuit EMDC and the gate drive circuit GDC and described below, the second lower conductive layer BML″ is electrically connected to the counter electrode 230 to apply the common voltage ELVSS. Thus, the counter electrode 230 needs to be arranged inside only compared to the related art so that the peripheral area PA may be reduced, and additional design of holes above the emission drive circuit EMDC is unnecessary, thereby simultaneously implementing an effect of simplifying the process. As a result, according to the display apparatus 1 according to an embodiment, the size of the peripheral area PA may be reduced while the sizes of the main and corner display areas FDA and CDA may be increased, thereby preventing the voltage drop of the common voltage ELVSS.

The second lower conductive layer BML″ in contact with the common power supply wire VSL may be electrically connected to the counter electrode 230 in the valley area VLA and may transmit the common voltage ELVSS. The valley area VLA is included in the peripheral area PA, and may be arranged between the emission drive circuit EMDC and the gate drive circuit GDC. The valley area VLA may include the via valley VV formed in the organic insulating layer OL. The via valley VV may be formed through the first to fourth organic insulating layers OL1, OL2, OL3, and OL4 in a thickness direction. The via valley VV may separate the organic insulating layer OL overlapping the gate drive circuit GDC and the organic insulating layer OL overlapping the emission drive circuit EMDC. Accordingly, an out-gas generated in the area where the emission drive circuit EMDC is arranged may be restricted from being diffused to the area where the gate drive circuit GDC is arranged. In other words, as the out-gas may be prevented from being diffused to the main and corner display areas FDA and CDA, the reliability of the display apparatus 1 may be improved.

The second lower conductive layer BML″ may be electrically connected to the counter electrode 230 in the valley area VLA. In detail, the second lower conductive layer BML″ that receives the common voltage ELVSS through the common power supply wire VSL may be electrically connected to the counter electrode 230 through a power supply conductive layer CDL and the power supply electrode layer 214.

For example, the buffer layer 111, the first gate insulating layer 112, the second gate insulating layer 113, the first interlayer insulating layer 114, and the second interlayer insulating layer 115 may each include an opening in an area overlapping the via valley VV. The power supply conductive layer CDL may be disposed on the second interlayer insulating layer 115, and may contact the second lower conductive layer BML″ through the opening of the insulating layers. In other words, an upper surface of a part of the second lower conductive layer BML″ overlapping the via valley VV may be exposed by the opening of the insulating layers, and the exposed upper surface may be in direct contact with the power supply conductive layer CDL deposited thereon. The power supply conductive layer CDL may include the same material as those of the first source electrode S1 and the first drain electrode D1 of the first thin film transistor TFT1, and/or the common power supply wire VSL, and may be disposed on substantially the same layer.

Next, the power supply electrode layer 214 may be arranged on substantially the same layer as the first pixel electrode 210 and/or the second pixel electrode 212, and may extend from the second corner display area CDA2 to the peripheral area PA via the via valley VV.I The power supply electrode layer 214 may be in contact with the power supply conductive layer CDL in the via valley VV in which the organic insulating layer OL is removed. In other words, an upper surface of a part of the power supply conductive layer CDL in the via valley VV may be exposed by the via valley VV, and the exposed upper surface of the power supply conductive layer CDL may be in direct contact with the power supply electrode layer 214 deposited thereon.

As the counter electrode 230 may be deposed over the entire surface of the substrate 100, the counter electrode 230 may be disposed on the power supply electrode layer 214. According to the structure described above, the common voltage ELVSS applied through the common power supply wire VSL may be transmitted to the counter electrode 230 through the second lower conductive layer BML″, the power supply conductive layer CDL, and the power supply electrode layer 214. The second lower conductive layer BML″ may secure a sufficient area to overlap the emission drive circuit EMDC and the gate drive circuit GDC, as described above, the electrical resistance may be reduced and the voltage drop of the common voltage ELVSS may be reduced.

The scan control wires SCL may be arranged between the via valley VV and the gate drive circuit GDC, and the carry wires CL′ may be arranged between the via valley VV and the emission drive circuit EMDC. The scan control wires SCL, which is a wire for transmitting a scan control signal to the gate drive circuit GDC, may be arranged between the first organic insulating layer OL1 and the second organic insulating layer OL2. In an embodiment, the scan control wires SCL may include the same material as those of the first connection electrodes CM1 and CM1′, and may be disposed on substantially the same layer. The carry wires CL′, which is a wire for transmitting the output signal of the front-/rear-end stages, may be arranged between the second interlayer insulating layer 115 and the first organic insulating layer OL1. In an embodiment, the carry wires CL′ may include the same material as those of the first source electrode S1 and/or the first drain electrode D1 of the first thin film transistor TFT1, and may be disposed on substantially the same layer. In other words, the scan control wires SCL and the carry wires CL′ may be disposed on different layers.

When the scan control wires SCL and the carry wires CL′ are disposed on different layers, the width d2 of FIG. 11 of the valley area VLA may be reduced. For example, when the scan control wires SCL and the carry wires CL′ are disposed on the same layer, the scan control wires SCL and the carry wires CL′ may generate parasitic capacitance, and thus a sufficient distance may be secured in a plan view. In contrast, when the scan control wires SCL and the carry wires CL′ are disposed on different layers, an insulating layer disposed therebetween may secure a sufficient distance, and thus, a distance in a plan view may be reduced. Accordingly, the width of the valley area VLA arranged between the scan control wires SCL and the carry wires CL′ may be reduced, and thus, the size of the peripheral area PA may be reduced and the sizes of the main and corner display areas FDA and CDA may be increased. The scan control wires SCL and the carry wires CL′ are not limited to the structure as illustrated in FIG. 12, and the structure thereof may be appropriately altered so that the scan control wires SCL and the carry wires CL′ are disposed on different layers.

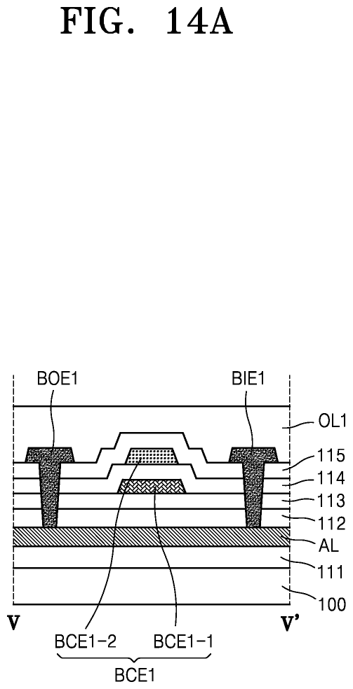

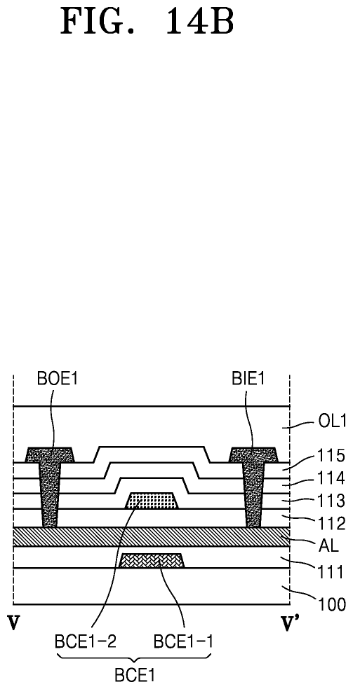

FIG. 13 is a schematic plan view of a buffer transistor BTFT of a display apparatus according to an embodiment. FIG. 14A is a schematic cross-sectional view of a portion of a display apparatus according to an embodiment, which corresponds to a cross-section taken along a line V-V′ of FIG. 13. FIG. 14B is a schematic cross-sectional view of a portion of a display apparatus according to another embodiment, which corresponds to a cross-section taken along a line V-V′ of FIG. 13

The buffer transistor BTFT of FIG. 13 is a schematic plan view of the scan stages GST of FIG. 11 and the first buffer transistor BF1 and the second buffer transistor BF2 in each of the light-emitting stages EST.

Referring to FIG. 13, the buffer transistor BTFT may include a semiconductor layer AL. In an embodiment, the semiconductor layer AL of the first buffer transistor BF1 and the semiconductor layer AL of the second buffer transistor BF2 may be integrally formed. The semiconductor layer AL may be a low-temperature polycrystalline silicon (LTPS) semiconductor or an oxide semiconductor layer. However, the disclosure is not limited thereto.

Next, the buffer transistor BTFT may include a first electrode branched from a signal input line. In an embodiment, the first electrode may include a first branch input electrode BIE1 branched form the gate high voltage wire. Each of the first branch input electrodes BIE1 may extend from the gate high voltage wire in the first direction (for example, the x direction), and the first branch input electrodes BIE1 may be arranged to be separated from each other in the second direction (for example, the y direction). The first branch input electrode BIE1 may overlap the semiconductor layer AL in a plan view. In particular, the first branch input electrodes BIE1 may contact the semiconductor layer AL through the contact hole.

The buffer transistor BTFT may include a second electrode arranged to be separated from the first electrode on the semiconductor layer AL. The second electrode may include a plurality of first branch output electrodes BOE1 arranged to be separated from the first branch input electrodes BIE1. The first branch output electrodes BOE1 may extend in the first direction (for example, the x direction), and the first branch output electrodes BOE1 may be arranged to be separated from each other in the second direction (for example, the y direction). One of the first branch input electrodes BIE1 may be arranged between the first branch output electrodes BOE1 separated from each other. In particular, the first branch output electrode BOE1 may be in contact with the semiconductor layer AL through the contact hole.

The buffer transistor BTFT may further include a control electrode CE1, and the control electrode CE1 may include a plurality of first branch control electrodes BCE1. The first branch control electrodes BCE1 may extend in the first direction (for example, the x direction), like the first branch input electrodes BIE1, and the first branch control electrodes BCE1 may be arranged to be separated from each other in the second direction (for example, the y direction).

Each of the first branch control electrodes BCE1 may be arranged between one first branch input electrode BIE1 and one first branch output electrode BOE1 facing each other. However, in an embodiment, the first branch control electrodes BCE1 may have a structure in which metal layers overlap each other. The structure of the first branch control electrodes BCE1 is described below in detail with reference to FIGS. 14A and 14B. In one embodiment, both the first buffer transistor BF1 and the second buffer transistor BF2 may include the structure shown in FIG. 14A or the structure shown in FIG. 14B. In another embodiment, the first buffer transistor BF1 may include the structure shown in FIG. 14B, and the second buffer transistor BF2 may include the structure shown in FIG. 14A. However, the present invention is not limited thereto, and the first buffer transistor BF1 may include the structure shown in FIG. 14A, and the second buffer transistor BF2 may include the structure shown in FIG. 14B.

As such, as a first electrode, a second electrode, and a control electrode of the buffer transistor BTFT are arranged in the form of branch electrodes, the overall channel width of the buffer transistor BTFT may be increased. By increasing the overall channel width of the buffer transistor BTFT in a limited space, without increasing the width of the peripheral area PA, the operation characteristics of the buffer transistor BTFT may be improved.

Referring to FIG. 14A, the buffer layer 111 may be formed on the substrate 100, and the semiconductor layer AL, the first gate insulating layer 112, the second gate insulating layer 113, and the first branch control electrode BCE1 may be sequentially formed thereon. The semiconductor layer AL may include a channel region overlapping the first branch control electrode BCE1 and conductive layers disposed on both sides of the channel region which does not overlap the first branch control electrode BCE1.

The first branch control electrode BCE1 may include a first metal layer BCE1-1 and a second metal layer BCE1-2. In other words, the first branch control electrode BCE1 may have a structure in which the first metal layer BCE1-1 and the second metal layer BCE1-2 overlap each other and the second metal layer BCE1-2 is stacked on the first metal layer BCE1-1 with an insulating layer 114 disposed therebetween. The first metal layer BCE1-1 and the second metal layer BCE1-2 may be electrically connected to each other via the contact hole (not shown).

In an embodiment, the first metal layer BCE1-1 may be arranged between the second gate insulating layer 113 and the first interlayer insulating layer 114, may include the same material as that of the second gate layer, and may be disposed on substantially the same layer as the second gate layer. For example, the first metal layer BCE1-1 may include Al, Pt, Pd, Ag, Mg, Au, Ni, Nd, Ir, Cr, Ca, Mo, Ti, W, and/or Cu, and may be a single layer or multilayer including the material described above. Furthermore, the second metal layer BCE1-2 may be arranged between the first interlayer insulating layer 114 and the second interlayer insulating layer 115, may include the same material as that of the third gate layer, and may be disposed on substantially the same layer as the third gate layer. For example, the second metal layer BCE1-2 may include Al, Pt, Pd, Ag, Mg, Au, Ni, Nd, Ir, Cr, Ca, Mo, Ti, W, and/or Cu, and may be a single layer or multilayer including the material described above.

The second interlayer insulating layer 115 may be formed on the second metal layer BCE1-2 of the first branch control electrode BCE1. Next, a contact hole may be formed by removing partial areas of the first gate insulating layer 112, the second gate insulating layer 113, the first interlayer insulating layer 114, and the second interlayer insulating layer 115, which are arranged on and above the upper area of the semiconductor layer AL. The first branch input electrode BIE1 and the first branch output electrode BOE1, which extend parallel to the first branch control electrode BCE1, may be formed on the second interlayer insulating layer 115, and the first branch input electrode BIE1 and the first branch output electrode BOE1 may each be electrically connected to the semiconductor layer AL through the contact hole. The first branch input electrode BIE1 and the first branch output electrode BOE1 may each include Al, Pt, Pd, Ag, Mg, Au, Ni, Nd, Ir, Cr, Ca, Mo, Ti, W, and/or Cu, and may each be a single layer or multilayer including the material described above.

As the first branch control electrode BCE1 of the buffer transistor BTFT has a structure (a double gate structure) in which the first metal layer BCE1-1 and the second metal layer BCE1-2 overlap each other, while the size of the buffer transistor BTFT is reduced, the operation characteristics of the buffer transistor BTFT may be improved. As the first metal layer BCE1-1 and the second metal layer BCE1-2 are electrically connected to each other through the contact hole, the first metal layer BCE1-1 and the second metal layer BCE1-2 may serve to transmit the same signal. As the first metal layer BCE1-1 and the second metal layer BCE1-2 are arranged to overlap each other in a plan view, while the area of the first branch control electrode BCE1 in a plan view is reduced, as the first branch control electrode BCE1 includes the first metal layer BCE1-1 and the second metal layer BCE1-2, a sufficient area may be secured. Accordingly, when the first branch control electrode BCE1 uses the double gate structure, a width d3 of FIG. 13 and the area of the buffer transistor BTFT in a plan view may be reduced. As a result, the display apparatus 1 according to an embodiment may reduce the area of the buffer transistor BTFT to reduce the area of the peripheral area PA of FIG. 12 and increase the display areas FDA and CDA of FIG. 12, thereby improving the operation characteristics of the buffer transistor BTFT.

Next, FIG. 14B is a schematic cross-sectional view of a portion of the buffer transistor BTFT according to another embodiment. Referring to FIG. 14B, except the characteristics of the first branch control electrode BCE1, the other characteristics are as those described with reference to FIGS. 11 to 14A. Like reference numerals of the constituent elements of FIG. 14B are the same as those described above with reference to FIGS. 11 to 14A, and only differences are described in the following description.

Referring to FIG. 14B, the first metal layer BCE1-1 of the first branch control electrode BCE1 may be formed on the substrate 100, and the buffer layer 111 may be formed thereon. Next, the semiconductor layer AL, the first gate insulating layer 112, and the second metal layer BCE1-2 of the first branch control electrode BCE1 may be sequentially formed on the buffer layer 111.

In other words, in an embodiment, the first metal layer BCE1-1 may be arranged between the substrate 100 and the buffer layer 111, may include the same material as those of the lower conductive layers BML, BML′, and BML″ of FIG. 12, and may be disposed on substantially the same layer as the first-1, first-2, and second lower conductive layers BML, BML′, and BML″. For example, the first metal layer BCE1-1 may include a low-resistance conductive material, such as Mo, Al, Cu, and/or Ti, and may have a single layer or multilayer structure including the materials described above. Furthermore, the second metal layer BCE1-2 may be arranged between the first gate insulating layer 112 and the second gate insulating layer 113, may include the same material as that of the first gate electrode G1 of FIG. 12 of the first transistor TFT1 of FIG. 12, and may be disposed on substantially the same layer as the first gate electrode G1. For example, the second metal layer BCE1-2 may include Mo, Al, Cu, Ti, and/or the like, and may be formed of a single layer or multilayer.

The second gate insulating layer 113, the first interlayer insulating layer 114, and the second interlayer insulating layer 115 may be sequentially formed on the second metal layer BCE1-2 of the first branch control electrode BCE1. Next, a contact hole may be formed by removing partial areas of the first gate insulating layer 112, the second gate insulating layer 113, the first interlayer insulating layer 114, and the second interlayer insulating layer 115, which are arranged on the upper area of the semiconductor layer AL. The first branch input electrode BIE1 and the first branch output electrode BOE1, which extend parallel to the first branch control electrode BCE1, may be formed on the second interlayer insulating layer 115, and the first branch input electrode BIE1 and the first branch output electrode BOE1 may each be electrically connected to the semiconductor layer AL through the contact hole.

As the first branch control electrode BCE1 has a structure (a double gate structure) in which the first metal layer BCE1-1 and the second metal layer BCE1-2 overlap each other, the buffer transistor BTFT having the same structure as illustrated in FIG. 14B may improve the operation characteristics of the buffer transistor BTFT while reducing the size of the buffer transistor BTFT. As described above, as the first metal layer BCE1-1 and the second metal layer BCE1-2 are arranged to overlap each other in a plan view, when the width of the buffer transistor BTFT in a plan view is reduce, a sufficient area of the first branch control electrode BCE1 may be secured. As a result, according to the display apparatus 1 according to another embodiment, by reducing the size of the buffer transistor BTFT, the area of the peripheral area PA of FIG. 12 may be reduced, and while the sizes of the display areas FDA and CDA of FIG. 12 are increased, the operation characteristics of the buffer transistor BTFT may be improved.

However, as described above, the buffer transistor BTFT may be included in each of the emission drive circuit EMDC and the gate drive circuit GDC, and the second lower conductive layer BML″ may be arranged to overlap the emission drive circuit EMDC and the gate drive circuit GDC. As illustrated in FIG. 14B, when the first metal layer BCE1-1 of the first branch control electrode BCE1 is used as the same layer as the first-1, first-2, and second lower conductive layers BML, BML′, and BML″, the second lower conductive layer BML″ may extend only in an area except the first metal layer BCE1-1. In detail, while the second lower conductive layer BML″ extends to overlap the emission drive circuit EMDC and the gate drive circuit GDC, in an area where the buffer transistor BTFT of each of the emission drive circuit EMDC and the gate drive circuit GDC is arranged, the second lower conductive layer BML″ may extend by using a bridge wire. The bridge wire may not be arranged on the same layer as the first-1, first-2, and second lower conductive layers BML, BML′, and BML″, and a metal layer disposed on different layers may be used therefor. Through the structure described above, in the display apparatus according to another embodiment as illustrated in FIG. 14, while the voltage drop of the common voltage ELVSS is prevented by using the second lower conductive layer BML″, by using the double gate structure of the first branch control electrode BCE1, an effect of reducing the size of the buffer transistor BTFT may be simultaneously implemented.

In the display apparatus according to the embodiments as described above, the corner display area is provided so that an area for displaying an image may be expanded. In addition, by reducing the area contacted by the common voltage supply wire, the display area may be secured as large as possible. The effect described above is an example, and the scope of the disclosure is not limited by the above effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate comprising a front display area, a first corner display area extending from a corner of the front display area, a second corner display area extending from the first corner display area, and a peripheral area surrounding the front display area and the second corner display area;
a main pixel circuit disposed on the substrate and arranged in the front display area;
a first lower conductive layer arranged between the substrate and the main pixel circuit;
a common power supply wire arranged in the peripheral area;
an emission drive circuit arranged in the peripheral area and located at an inner side than the common power supply wire;
a gate drive circuit arranged in the second corner display area; and
a second lower conductive layer arranged between the substrate and the emission drive circuit,
wherein the second lower conductive layer is electrically connected to the common power supply wire, and overlaps the emission drive circuit and the gate drive circuit.

2. The display apparatus of claim 1, wherein the second lower conductive layer comprises a same material and is disposed on substantially a same layer as the first lower conductive layer.

3. The display apparatus of claim 1, wherein the common power supply wire comprises a same material and is disposed on substantially a same layer as a source electrode or a drain electrode of the main pixel circuit.

4. The display apparatus of claim 1, wherein the second lower conductive layer extends to overlap each of the common power supply wire, the emission drive circuit, and the gate drive circuit, and is arranged to be separated from the first lower conductive layer.

5. The display apparatus of claim 1, wherein the second lower conductive layer is in direct contact with the common power supply wire through a contact hole.

6. The display apparatus of claim 1, further comprising:
an organic insulating layer disposed on the main pixel circuit, the gate drive circuit, and the emission drive circuit; and
a power supply electrode layer disposed on the organic insulating layer,
wherein the power supply electrode layer is electrically connected to the second lower conductive layer.

7. The display apparatus of claim 6, wherein the main pixel circuit is connected to a main light-emitting element, and the power supply electrode layer comprises a same material as a first electrode of the main light-emitting element, and is disposed on substantially a same layer as the first electrode.

8. The display apparatus of claim 6, wherein the power supply electrode layer comprises a plurality of holes in an area overlapping the gate drive circuit.

9. The display apparatus of claim 6, further comprising a power supply conductive layer arranged between the second lower conductive layer and the power supply electrode layer,
wherein the power supply conductive layer comprises a same material as the common power supply wire, and is disposed on substantially a same layer as the common power supply wire.

10. The display apparatus of claim 9, wherein the peripheral area further comprises a valley area arranged between the emission drive circuit and the gate drive circuit, and
wherein the second lower conductive layer, the power supply conductive layer, and the power supply electrode layer are electrically connected to one another in the valley area.

11. The display apparatus of claim 1, wherein each of the emission drive circuit and the gate drive circuit comprises a buffer transistor,
wherein the buffer transistor comprises an input electrode, an output electrode, and a control electrode, and
wherein the control electrode has a structure in which a first metal layer and a second metal layer overlap each other.

12. The display apparatus of claim 11, wherein the first metal layer and the second metal layer are disposed on different layers with an insulating layer interposed therebetween and are electrically connected to each other through a contact hole.

13. The display apparatus of claim 11, further comprising:
a buffer layer disposed on the first lower conductive layer and the second lower conductive layer;
a semiconductor layer disposed on the buffer layer;
a first gate insulating layer disposed on the semiconductor layer;
a first gate layer disposed on the first gate insulating layer;
a second gate insulating layer disposed on the first gate layer;
a second gate layer disposed on the second gate insulating layer;
a first interlayer insulating layer disposed on the second gate layer; and
a third gate layer disposed on the first interlayer insulating layer.

14. The display apparatus of claim 13, wherein the first metal layer comprises a same material and is disposed on substantially a same layer as the second lower conductive layer, and
wherein the second metal layer comprises a same material and is disposed on substantially a same layer as the first gate layer.

15. The display apparatus of claim 13, wherein the first metal layer comprises a same material and is disposed on substantially a same layer as the second gate layer, and
wherein the second metal layer comprises a same material and is disposed on substantially a same layer as the third gate layer.

16. The display apparatus of claim 13, wherein the buffer transistor comprises a first buffer transistor and a second buffer transistor,
wherein a first metal layer of the first buffer transistor and a first metal layer of the second buffer transistor are disposed on different layers, and
wherein the second metal layer of the first buffer transistor and the second metal layer of the second buffer transistor are disposed on different layers.

17. The display apparatus of claim 16, wherein the first metal layer of the first buffer transistor is disposed on substantially a same layer as the second lower conductive layer,
wherein the second metal layer of the first buffer transistor is disposed on substantially a same layer as the first gate layer,
wherein the first metal layer of the second buffer transistor is disposed on substantially a same layer as the second gate layer, and
wherein the second metal layer of the second buffer transistor is disposed on substantially a same layer as the third gate layer.

18. The display apparatus of claim 1, further comprising:
first signal input lines through which signals are input to the emission drive circuit; and
second signal input lines through which signals are input to the gate drive circuit,
wherein some lines of the first signal input lines and some lines of the second signal input lines are disposed on different layers.

19. The display apparatus of claim 18, further comprising:
a first organic insulating layer covering the main pixel circuit; and
a first connection electrode disposed on the first organic insulating layer and connecting the main pixel circuit with a main light-emitting element,
wherein the first signal input lines are disposed on substantially a same layer as a source electrode or a drain electrode of the main pixel circuit, and
wherein the second signal input lines are disposed on substantially a same layer as the first connection electrode.

20. A display apparatus comprising:
a substrate comprising a display area and a peripheral area surrounding the display area;
an emission drive circuit disposed on the substrate; and
a gate drive circuit disposed on the substrate and arranged closer to the display area than the emission drive circuit,
wherein each of the emission drive circuit and the gate drive circuit comprises a buffer transistor,
wherein the buffer transistor comprises an input electrode, an output electrode, and a control electrode, and
wherein the control electrode has a structure in which a first metal layer and a second metal layer overlap each other.

21. The display apparatus of claim 20, wherein the first metal layer and the second metal layer are disposed on different layers with an insulating layer disposed therebetween and are electrically connected to each other through a contact hole.

22. The display apparatus of claim 20, further comprising:
first signal input lines through which signals are input to the emission drive circuit; and
second signal input lines through which signals are input to the gate drive circuit,
wherein some lines of the first signal input lines and some lines of the second signal input lines are disposed on different layers.

23. The display apparatus of claim 20, further comprising:
a pixel circuit disposed on the substrate and arranged in the display area;
a first lower conductive layer arranged between the substrate and the pixel circuit;
a common power supply wire arranged in the peripheral area; and
a second lower conductive layer electrically connected to the common power supply wire,
wherein the first lower conductive layer and the second lower conductive layer are disposed on substantially a same layer, and
wherein the second lower conductive layer overlaps the emission drive circuit and the gate drive circuit.
